(19) United States
(12) Patent Application Publication
(10) Pub. No.: US 2026/0260608 A1
(43) Pub. Date: Sep. 3, 2026

(54) DISPLAY SUBSTRATE AND DETECTION METHOD THEREFOR, AND DISPLAY DEVICE

(71) Applicants: HEFEI BOE JOINT TECHNOLOGY CO., LTD., Hefei, Anhui (CN); BOE TECHNOLOGY GROUP CO., LTD., Beijing (CN)

(72) Inventors: Xuehuan FENG, Beijing (CN); Biao TIAN, Beijing (CN); Junqi HAN, Beijing (CN)

(73) Assignees: HEFEI BOE JOINT TECHNOLOGY CO., LTD., Hefei, Anhui (CN); BOE TECHNOLOGY GROUP CO., LTD., Beijing (CN)

(21) Appl. No.: 18/994,472

(22) PCT Filed: Apr. 23, 2023
(86) PCT No.: PCT/CN2023/090122

§ 371 Date: Jan. 14, 2025

(51) Int. Cl. G09G 3/3233; H10K 59/131

(52) U.S. Cl. CPC G09G 3/3233; G09G 2300/0842; G09G 2310/08; G09G 2320/0257; G09G 2330/12; H10K 59/131

(57) ABSTRACT

Provided are a display substrate and a detection method therefor, and a display device. In the display substrate, a control terminal of the sensing sub-circuit is electrically connected to the sensing scan signal line, the sensing sub-circuit is configured to detect the electrical characteristic of the sub-pixel to which the sensing sub-circuit belongs through the sensing signal line in response to the sensing scan signal; among the plurality of sub-pixels of the display unit, the pixel circuit of at least one sub-pixel includes a detection control sub-circuit, a control terminal of the detection control sub-circuit is electrically connected to the detection scan signal line to receive the detection scan signal, a first terminal of the detection control sub-circuit is electrically connected to a second terminal of the sensing sub-circuit, and a second terminal of the detection control sub-circuit is electrically connected to the sensing signal line.

### TECHNICAL FIELD

At least one embodiment of the present disclosure relates to a display substrate, a detection method thereof, and a display device.

### BACKGROUND

Organic Light-emitting Diode (OLED) display devices are gradually attracting extensive attention due to their advantages such as wide viewing angle, high contrast, fast response speed, and higher luminance and lower driving voltage than inorganic light-emitting display devices. Due to the above characteristics, organic light-emitting diodes (OLEDs) can be applied to devices with display functions such as mobile phones, monitors, laptops, digital cameras, instruments and meters.

Pixel circuits in OLED display devices generally adopt matrix driving methods, which can be divided into active matrix (AM) driving and passive matrix (PM) driving according to whether switching component is introduced in each pixel unit. Although PMOLED is provided by simple process and with low cost, it cannot meet the requirement of high-resolution and large-size display due to shortcomings such as crosstalk, high power consumption, and short lifespan. In contrast, AMOLED integrates a set of thin film transistors and storage capacitor(s) into the pixel circuit of each pixel, and achieves the control of the current flowing through the OLED through driving and controlling the thin film transistors and storage capacitor(s), so that the OLED can emit light as needed. Compared with PMOLED, AMOLED requires small driving current, low power consumption, and has a longer life, and can meet the requirement for large-size display with high resolution and multiple grayscales. Moreover, AMOLED has obvious advantages in viewing angle, color reproduction, power consumption and response time, and is suitable for display devices with high information content and high resolution.

### SUMMARY

At least one embodiment of the present disclosure provides a display substrate, the display substrate includes a display unit located in a display region and performing a display function, the display unit includes a plurality of sub-pixels, and each of the plurality of sub-pixels includes a pixel circuit; the pixel circuit includes a driving sub-circuit, a light-emitting element and a sensing sub-circuit; a first terminal of the sensing sub-circuit is electrically connected to a first terminal of the driving sub-circuit and a first electrode of the light-emitting element; the display substrate includes a sensing signal line, a sensing scan signal line and a detection scan signal line, a control terminal of the sensing sub-circuit is electrically connected to the sensing scan signal line, the sensing sub-circuit is configured to detect the electrical characteristic of the sub-pixel to which the sensing sub-circuit belongs through the sensing signal line in response to the sensing scan signal; among the plurality of sub-pixels of the display unit, the pixel circuit of at least one sub-pixel includes a detection control sub-circuit, a control terminal of the detection control sub-circuit is electrically connected to the detection scan signal line to receive the detection scan signal, a first terminal of the detection control sub-circuit is electrically connected to a second terminal of the sensing sub-circuit, and a second terminal of the detection control sub-circuit is electrically connected to the sensing signal line.

For example, in the display substrate provided by at least one embodiment of the present disclosure, a plurality of detection control sub-circuits included in the plurality of sub-pixels in the display unit are electrically connected to a same one of the sensing signal line, and the control terminals of the plurality of detection control sub-circuits are respectively electrically connected to different ones of the sensing signal lines.

For example, in the display substrate provided by at least one embodiment of the present disclosure, the pixel circuit further comprises a storage sub-circuit and a data writing sub-circuit, the data writing sub-circuit is configured to write a data signal to a control terminal of the driving sub-circuit in response to a data scan signal; the driving sub-circuit comprises a driving transistor, a gate electrode of the driving transistor is electrically connected to a first terminal of the storage sub-circuit, a first electrode of the driving transistor is electrically connected to a second terminal of the storage sub-circuit, and is electrically connected to the light-emitting element, a second electrode of the driving transistor is configured to receive a first power supply voltage, and the driving transistor is configured to control a current for driving the light-emitting element under a control of a voltage of the gate electrode of the driving transistor; the sensing sub-circuit comprises a sensing transistor, the detection control sub-circuit comprises a detection control transistor, a gate electrode of the sensing transistor is electrically connected to the sensing scan signal line, a first electrode of the sensing transistor is electrically connected to a first electrode of the driving transistor and a second terminal of the storage sub-circuit, a second electrode of the sensing transistor is electrically connected to a first electrode of the detection control transistor, and a second electrode of the detection control transistor is electrically connected to the sensing signal line, a gate electrode of the detection control transistor is electrically connected to the detection scan signal line.

For example, in the display substrate provided by at least one embodiment of the present disclosure, the plurality of sub-pixels of the display unit comprise a first sub-pixel and a second sub-pixel; and the detection control sub-circuit comprises a first detection control sub-circuit and a second detection control sub-circuit; a second terminal of the sensing sub-circuit of the first sub-pixel is electrically connected to the sensing signal line through the first detection control sub-circuit; a second terminal of the sensing sub-circuit of the second sub-pixel is electrically connected to the sensing signal line through the second detection control sub-circuit; the detection scan signal line comprises a first detection scan signal line and a second detection scan signal line, a control terminal of the first detection control sub-circuit is electrically connected to the first detection scan signal line to receive a first detection scan signal, a first terminal of the first detection control sub-circuit is electrically connected to a second terminal of the sensing sub-circuit of the first sub-pixel, and a second terminal of the first detection control sub-circuit is electrically connected to the sensing signal line; a control terminal of the second detection control sub-circuit is electrically connected to the second detection scan signal line to receive a second detection scan signal, a first terminal of the second detection control sub-circuit is electrically connected to a second terminal of the sensing sub-circuit of the second sub-pixel, and a second terminal of the second detection control sub-circuit is electrically connected to a same one sensing signal line as the sensing signal line.

For example, in the display substrate provided by at least one embodiment of the present disclosure, the first detection control sub-circuit comprises a first detection control transistor, the second detection control sub-circuit comprises a second detection control transistor; a first electrode of the first detection control transistor is electrically connected to a second electrode of the sensing transistor of the first sub-pixel, a first electrode of the second detection control transistor is electrically connected to a second electrode of the sensing transistor of the second sub-pixel, a second electrode of the first detection control transistor and a second electrode of the second detection control transistor are respectively electrically connected to the same one sensing signal line; a gate electrode of the first detection control transistor is electrically connected to the first detection scan signal line to receive a first detection scan signal, and a gate electrode of the second detection control transistor is electrically connected to the second detection scan signal line to receive a second detection scan signal.

For example, in the display substrate provided by at least one embodiment of the present disclosure, the plurality of sub-pixels of the display unit further comprises a third sub-pixel, and a second terminal of the sensing sub-circuit of the third sub-pixel is electrically connected to the first terminal of the first detection control sub-circuit.

For example, in the display substrate provided by at least one embodiment of the present disclosure, the plurality of sub-pixels of the display unit further comprises a third sub-pixel, and a pixel circuit of the third sub-pixel further comprises a third detection control sub-circuit; the detection scan signal line comprises a third detection scan signal line, a control terminal of the third detection control sub-circuit is electrically connected to the third detection scan signal line to receive a third detection scan signal, a first terminal of the third detection control sub-circuit is electrically connected to a second terminal of the sensing sub-circuit of the third sub-pixel, and a second terminal of the third detection control sub-circuit is electrically connected to the sensing signal line.

For example, in the display substrate provided by at least one embodiment of the present disclosure, the third detection control sub-circuit comprises a third detection control transistor, a gate electrode of the third detection control transistor is electrically connected to the third detection scan signal line, a first electrode of the third detection control transistor is electrically connected to a second electrode of a sensing transistor of the third sub-pixel, and a second electrode of the third detection control transistor is electrically connected to the sensing signal line.

For example, in the display substrate provided by at least one embodiment of the present disclosure, the plurality of sub-pixels of the display unit further comprises a third sub-pixel, and a pixel circuit of the third sub-pixel further comprises a third detection control sub-circuit; the detection scan signal line comprises a third detection scan signal line, a control terminal of the third detection control sub-circuit is electrically connected to the third detection scan signal line to receive a third detection scan signal, a first terminal of the third detection control sub-circuit is electrically connected to a second terminal of the sensing sub-circuit of the third sub-pixel, and a second terminal of the third detection control sub-circuit is electrically connected to the first terminal of the first detection control sub-circuit.

For example, in the display substrate provided by at least one embodiment of the present disclosure, the third detection control sub-circuit comprises a third detection control transistor, a gate electrode of the third detection control transistor is electrically connected to the third detection scan signal line, and is configured to receive the third detection scan signal, a first electrode of the third detection control transistor is electrically connected to a second electrode of the sensing transistor of the third sub-pixel, and a second electrode of the third detection control transistor is electrically connected to a first electrode of the first detection control transistor.

For example, in the display substrate provided by at least one embodiment of the present disclosure, the plurality of sub-pixels of the display unit further comprises a fourth sub-pixel, and a second terminal of the sensing sub-circuit of the fourth sub-pixel is electrically connected to the first terminal of the second detection control sub-circuit, and the second terminal of the second detection control sub-circuit is electrically connected to the sensing signal line.

For example, in the display substrate provided by at least one embodiment of the present disclosure, the plurality of sub-pixels of the display unit further comprises a fourth sub-pixel, and a pixel circuit of the fourth sub-pixel further comprises a fourth detection control sub-circuit; the detection scan signal line comprises a fourth detection scan signal line, a control terminal of the fourth detection control sub-circuit is electrically connected to the fourth detection scan signal line to receive a fourth detection scan signal, a first terminal of the fourth detection control sub-circuit is electrically connected to a second terminal of the sensing sub-circuit of the fourth sub-pixel, and a second terminal of the fourth detection control sub-circuit is electrically connected to the sensing signal line.

For example, in the display substrate provided by at least one embodiment of the present disclosure, the fourth detection control sub-circuit comprises a fourth detection control transistor, a gate electrode of the fourth detection control transistor is electrically connected to the fourth detection scan signal line to receive the fourth detection scan signal, a first electrode of the fourth detection control transistor is electrically connected to a second electrode of the sensing transistor of the fourth sub-pixel, and a second electrode of the fourth detection control transistor is electrically connected to the sensing signal line.

For example, in the display substrate provided by at least one embodiment of the present disclosure, the plurality of sub-pixels of the display unit further comprises a fourth sub-pixel, and a pixel circuit of the fourth sub-pixel further comprises a fourth detection control sub-circuit; the detection scan signal line comprises a fourth detection scan signal line, a control terminal of the fourth detection control sub-circuit is electrically connected to the fourth detection scan signal line to receive the fourth detection scan signal, a first terminal of the fourth detection control sub-circuit is electrically connected to a second terminal of the sensing sub-circuit of the fourth sub-pixel, and a second terminal of the fourth detection control sub-circuit is electrically connected to a first terminal of the second detection control sub-circuit.

For example, in the display substrate provided by at least one embodiment of the present disclosure, the fourth detection control sub-circuit comprises a fourth detection control transistor, a gate electrode of the fourth detection control transistor is configured to receive the fourth detection scan signal, a first electrode of the fourth detection control transistor is electrically connected to a second electrode of the sensing transistor of the fourth sub-pixel, and a second electrode of the fourth detection control transistor is electrically connected to a first electrode of the second detection control transistor.

At least one embodiment of the present disclosure further provides a detection method applied to any one of the above-mentioned display substrates provided by the embodiment of the present disclosure, the detection method includes: performing at least two times of detections on at least one sub-pixel among the plurality of sub-pixels of the display unit, and performing at least two times of detections on electrical signals on the sensing signal line, which specifically comprises: in a first detection, turning on detection control transistors of all the sub-pixels included in the display unit, and if an electrical signal on the sensing signal line is abnormal, then performing a next detection; in a next detection, turning off a detection control transistor of at least one sub-pixel among the plurality of sub-pixel in the display unit to detect other sub-pixels in the display unit again; determining whether the plurality of sub-pixels are abnormal based on the electrical signals on the sensing signal line obtained by the two times of detections; and for an abnormal sub-pixel, obtaining a threshold voltage of a driving sub-circuit of a sub-pixel with a same color as the abnormal sub-pixel and without abnormality in another display unit as a threshold voltage of the driving sub-circuit of the abnormal sub-pixel for a compensation on the abnormal sub-pixel.

For example, in the detection method provided by at least one embodiment of the present disclosure, the pixel circuit further comprises a data writing sub-circuit, the data writing sub-circuit is configured to write a data signal to a control terminal of the driving sub-circuit in response to a data scan signal; performing at least two times of detections on at least one sub-pixel among the plurality of sub-pixels of the display unit comprises: using the at least one sub-pixel among the plurality of sub-pixels of the display unit as a test sub-pixel to perform the two times of detections, during a process of performing the two times of detections on the test sub-pixel, the data signal is written to the test sub-pixel and the data signal is not written to other sub-pixels except the test sub-pixel, and the first detection scan signal and the second detection scan signal in the first detection to be not completely same as the first detection scan signal and the second detection scan signal in the second detection in the process of the two times of detections are controlled.

For example, in the detection method provided by at least one embodiment of the present disclosure, the detection method comprises: in the first detection, turning on the detection control transistors of all the sub-pixels included in the display unit, and performing the first detection on an electrical signal on the sensing signal line, if a detected detection signal on the sensing signal line is abnormal, then it indicates that at least one sub-pixel among the plurality of sub-pixels in the display unit has a short circuit problem of a sensing transistor, then randomly turning off the detection control transistor of at least one sub-pixel among the plurality of sub-pixels in the display unit, and performing a second detection using a sub-pixel being not turned off as the test sub-pixel; and in the second detection, if a detected detection signal on the sensing signal line is abnormal, then it indicates that another sub-pixel except the sub-pixel whose detection control transistor is turned off has a short circuit problem of the sensing transistor, if a detected detection signal on the sensing signal line is normal, it indicates that at least one sub-pixel among the plurality of sub-pixels whose detection control transistor is turned off has a short circuit problem of the sensing transistor.

For example, in the detection method provided by at least one embodiment of the present disclosure, in a case that the plurality of sub-pixels in the display unit comprises a first sub-pixel and a second sub-pixel, the first sub-pixel comprises a first detection control transistor, the second sub-pixel comprises a second detection control transistor, a first electrode of the first detection control transistor is electrically connected to a second electrode of a sensing transistor of the first sub-pixel, a first electrode of the second detection control transistor is electrically connected to a second electrode of a sensing transistor of the second sub-pixel, and a second electrode of the first detection control transistor and a second electrode of the second detection control transistor are respectively electrically connected to a same one sensing signal line as the sensing signal line, a gate electrode of the first detection control transistor is electrically connected to a first detection scan signal line to receive a first detection scan signal, and a gate electrode of the second detection control transistor is electrically connected to a second detection scan signal line to receive a second detection scan signal, the detection method comprises: in the first detection, turning on both the first detection control transistor and the second detection control transistor, in response to a detected detection signal of the sensing signal line being abnormal, randomly turning off the first detection control transistor or the second detection control transistor, and then using a sub-pixel whose detection control transistor is not turned off as the test sub-pixel to perform the second detection; and in the second detection, if a detected detection signal of the sensing signal line is abnormal, it indicates that the sensing transistor of the test sub-pixel is abnormal, if a detected detection signal of the sensing signal line is normal, it indicates that the sensing transistor of another sub-pixel except the test sub-pixel is abnormal.

For example, in the detection method provided by at least one embodiment of the present disclosure, in a case that the plurality of sub-pixels in the display unit further comprises a third sub-pixel, a pixel circuit of the third sub-pixel further comprises a third detection control sub-circuit, the detection scan signal line comprises a third detection scan signal line, a control terminal of the third detection control sub-circuit is electrically connected to the third detection scan signal line to receive a third detection scan signal, a first terminal of the third detection control sub-circuit is electrically connected to a second terminal of the sensing sub-circuit of the third sub-pixel, and a second terminal of the third detection control sub-circuit is electrically connected to the sensing signal line, the detection method comprises: using one sub-pixel among the plurality of sub-pixels in the display unit as the test sub-pixel to perform two times of detections on electrical signals on the sensing signal line, which specifically comprises: in the first detection, turning on detection control transistors of all sub-pixels included in the display unit, and performing the first detection on an electrical signal on the sensing signal line, if a detected detection signal on the sensing signal line is abnormal, then it indicates that at least one sub-pixel among the plurality of sub-pixels in the display unit has a short circuit problem of a sensing transistor, then randomly turning off detection control transistors of two sub-pixels except the test sub-pixel in the display unit, and performing a second detection on an electrical signal on the sensing signal line; and in the second detection, if a detected detection signal on the sensing signal line is normal, then it indicates that at least one of the two sub-pixels whose detection control transistors are turned off have a short circuit problem of a sensing transistor, if a detected detection signal on the sensing signal line is abnormal, it indicates that the test sub-pixel has a short circuit problem of a sensing transistor.

For example, in the detection method provided by at least one embodiment of the present disclosure, the data signal written to the other sub-pixels is a voltage signal of 0V.

At least one embodiment of the present disclosure further provides a display substrate, the display substrate includes a display unit, the display unit is located in a display region and performs a display function, the display unit comprises a plurality of sub-pixels, and each of the plurality of sub-pixels comprises a pixel circuit; the pixel circuit comprises: a driving sub-circuit, a light-emitting element and a sensing sub-circuit, the driving sub-circuit is configured to control a magnitude of a driving current flowing through the light-emitting element; a control terminal of the sensing sub-circuit is configured to receive a sensing scan signal, a first terminal of the sensing sub-circuit is electrically connected to a first terminal of the driving sub-circuit and a first electrode of the light-emitting element; the display substrate comprises a plurality of sensing signal lines, a second terminal of the sensing sub-circuit is electrically connected to a corresponding one sensing signal line among the plurality of sensing signal lines, and the sensing sub-circuit is configured to detect an electrical characteristic of the sub-pixel to which the sensing sub-circuit belongs through the sensing signal line electrically connected thereto in respond to the received sensing scan signal; the plurality of sub-pixels in the display unit comprises a first sub-pixel, a second sub-pixel and a third sub-pixel; a second terminal of a sensing sub-circuit of the first sub-pixel and a second terminal of the sensing sub-circuit of the second sub-pixel are electrically connected to a same one sensing signal line among the plurality of sensing signal lines, a second terminal of the sensing sub-circuit of the third sub-pixel and a second terminal of the sensing sub-circuit of the first sub-pixel are respectively electrically connected to different sensing signal lines, and a control terminal of the sensing sub-circuit of the first sub-pixel and a control terminal of the sensing sub-circuit of the second sub-pixel are respectively electrically connected to different sensing scan signal terminals to receive different sensing scan signals.

For example, in the display substrate provided by at least one embodiment of the present disclosure, a control terminal of the third sensing sub-circuit and a control terminal of the sensing sub-circuit of the first sub-pixel are electrically connected to a same sensing scan signal terminal to receive a same sensing scan signal, or, a control terminal of a sensing sub-circuit of the third sub-pixel and a control terminal of the sensing sub-circuit of the first sub-pixel are electrically connected to different sensing scan signal terminals to receive different sensing scan signals, respectively.

For example, in the display substrate provided by at least one embodiment of the present disclosure, the plurality of sub-pixels of the display unit further comprises a fourth sub-pixel, a second terminal of the sensing sub-circuit of the fourth sub-pixel and a second terminal of the sensing sub-circuit of the third sub-pixel are electrically connected to one same sensing signal line among the plurality of sensing signal lines, and, a control terminal of the sensing sub-circuit of the third sub-pixel and a control terminal of the sensing sub-circuit of the fourth sub-pixel are electrically connected to different sensing scan signal terminals to receive different sensing scan signals, respectively.

For example, in the display substrate provided by at least one embodiment of the present disclosure, a control terminal of a sensing sub-circuit of the second sub-pixel and a control terminal of the sensing sub-circuit of the fourth sub-pixel are respectively electrically connected to a same sensing scan signal terminal to receive a same sensing scan signal.

At least one embodiment of the present disclosure further provides a detection method applied to any one of the above-mentioned display substrates provided by the embodiment of the present disclosure, the detection method includes: applying different sensing scan signals respectively to a control terminal of the sensing sub-circuit of the first sub-pixel and a control terminal of the sensing sub-circuit of the second sub-pixel, so that the sensing sub-circuit of the first sub-pixel and the sensing sub-circuit of the second sub-pixel are electrically turned on in different time periods; and detecting electrical signals on the same sensing signal line electrically connected to a second terminal of the sensing sub-circuit of the first sub-pixel and a second terminal of the sensing sub-circuit of the second sub-pixel respectively during the time period in which the sensing sub-circuit of the first sub-pixel is electrically turned on and during the time period in which the sensing sub-circuit of the first sub-pixel is electrically turned on.

At least one embodiment of the present disclosure further provides a display device, and the display device includes any one of the display substrates provided by the embodiments of the present disclosure.

### BRIEF DESCRIPTION OF DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a block diagram of a display substrate provided by an embodiment of the present disclosure;

FIG. 2A is a schematic block diagram of a pixel circuit of a display unit provided by an embodiment of the present disclosure;

FIG. 2B is a circuit diagram of an implementation example of the pixel circuit illustrated in FIG. 2A;

FIG. 2C is a timing diagram of a pixel circuit of one sub-pixel illustrated in FIG. 2B during a display process;

FIG. 2C and FIG. 2D illustrate a signal timing diagram of a process in which the pixel circuit of one sub-pixel illustrated in FIG. 2B detects the electrical characteristic (e.g., threshold voltage) of the driving transistor;

FIG. 2E and FIG. 2F are examples of signal timing diagrams when detecting an abnormality in the pixel circuit illustrated in FIG. 2B;

FIG. 3A is a schematic block diagram of a pixel circuit of another type of display unit provided by an embodiment of the present disclosure;

FIG. 3B is a circuit diagram of an implementation example of the pixel circuit illustrated in FIG. 3A;

FIG. 4A is a schematic block diagram of a pixel circuit of another type of display unit provided by an embodiment of the present disclosure;

FIG. 4B is a circuit diagram of an implementation example of the pixel circuit illustrated in FIG. 4A;

FIG. 4C is an example of a signal timing diagram when detecting an abnormality in the pixel circuit illustrated in FIG. 4B;

FIG. 5A is a schematic block diagram of a pixel circuit of another type of display unit provided by an embodiment of the present disclosure;

FIG. 5B is a circuit diagram of an implementation example of the pixel circuit illustrated in FIG. 5A;

FIG. 6A is a schematic block diagram of a pixel circuit of another type of display unit provided by an embodiment of the present disclosure;

FIG. 6B is a circuit diagram of an implementation example of the pixel circuit illustrated in FIG. 6A;

FIG. 6C is an example of a signal timing diagram when detecting an abnormality in the pixel circuit illustrated in FIG. 6B;

FIG. 7A is a schematic block diagram of a pixel circuit of another type of display unit provided by an embodiment of the present disclosure;

FIG. 7B is a circuit diagram of an implementation example of the pixel circuit illustrated in FIG. 7A;

FIG. 8A is a schematic block diagram of a pixel circuit of another type display unit provided by an embodiment of the present disclosure;

FIG. 8B is a circuit diagram of an implementation example of the pixel circuit illustrated in FIG. 8A;

FIG. 8C is an example of a signal timing diagram when detecting an abnormality in the pixel circuit illustrated in FIG. 8B;

FIG. 9A is a schematic block diagram of a pixel circuit of another type of display unit provided by an embodiment of the present disclosure;

FIG. 9B is a circuit diagram of an implementation example of the pixel circuit illustrated in FIG. 9A;

FIG. 9C and FIG. 9D are examples of signal timing diagrams when detecting an abnormality in the pixel circuit illustrated in FIG. 9B;

FIG. 10A is a schematic block diagram of a pixel circuit of another type of display unit provided by an embodiment of the present disclosure;

FIG. 10B is a circuit diagram of an implementation example of the pixel circuit illustrated in FIG. 10A;

FIG. 11 is a schematic block diagram of a display device provided by an embodiment of the present disclosure.

### DETAILED DESCRIPTION

In order to make objects, technical details and advantages of the embodiments of the disclosure apparent, the technical solutions of the embodiments will be described in a clear and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms “comprise,” “comprising,” “comprise,” “comprising,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may comprise an electrical connection, directly or indirectly. “On,” “under,” “left,” “right” and the like are only used to indicate relative position relationship, and when the position of the object which is described is changed, the relative position relationship may be changed accordingly.

In the pixel circuits of some OLED display devices, an external compensation circuit is used to compensate the pixel circuit to mitigate the short-term afterimage problem that may occur due to the hysteresis effect of the display device. The threshold voltage of the driving transistor needs to be detected, so as to compensate according to the threshold voltage value. During the manufacturing process of display substrate with high-resolution, it is easy to cause short-circuit in some certain transistors, during the process of detecting the threshold voltage of the driving transistor, in the case that the transistor through which the detecting signal need to pass is short-circuited, the detected signal will be caused to be wrong, or even have a large deviation, which leads to an error in the measured threshold voltage value of the driving transistor, and normal compensation cannot be achieved for the pixel circuit where the abnormality occurs, resulting in abnormal display of the pixel where the pixel circuit is located, and formation of dotted line on the display panel.

At least one embodiment of the present disclosure provides a display substrate, the display substrate includes a display unit located in a display region and performing a display function, the display unit includes a plurality of sub-pixels, and each of the plurality of sub-pixels includes a pixel circuit; the pixel circuit includes a driving sub-circuit, a light-emitting element and a sensing sub-circuit; a first terminal of the sensing sub-circuit is electrically connected to a first terminal of the driving sub-circuit and a first electrode of the light-emitting element; the display substrate includes a sensing signal line, a sensing scan signal line and a detection scan signal line, a control terminal of the sensing sub-circuit is electrically connected to the sensing scan signal line, the sensing sub-circuit is configured to detect the electrical characteristic of the sub-pixel to which the sensing sub-circuit belongs through the sensing signal line in response to the sensing scan signal; among the plurality of sub-pixels of the display unit, the pixel circuit of at least one sub-pixel includes a detection control sub-circuit, a control terminal of the detection control sub-circuit is electrically connected to the detection scan signal line to receive the detection scan signal, a first terminal of the detection control sub-circuit is electrically connected to a second terminal of the sensing sub-circuit, and a second terminal of the detection control sub-circuit is electrically connected to the sensing signal line.

At least one embodiment of the present disclosure further provides a detection method applied to any one of the above-mentioned display substrates provided by the embodiment of the present disclosure, the detection method includes: performing at least two times of detections on at least one sub-pixel among the plurality of sub-pixels of the display unit, and performing at least two times of detections on electrical signals on the sensing signal line, which specifically comprises: in a first detection, turning on detection control transistors of all the sub-pixels included in the display unit, and if an electrical signal on the sensing signal line is abnormal, then performing a next detection; in a next detection, turning off a detection control transistor of at least one sub-pixel among the plurality of sub-pixel in the display unit to detect other sub-pixels in the display unit again; determining whether the plurality of sub-pixels are abnormal based on the electrical signals on the sensing signal line obtained by the two times of detections; and for an abnormal sub-pixel, obtaining a threshold voltage of a driving sub-circuit of a sub-pixel with a same color as the abnormal sub-pixel and without abnormality in another display unit as a threshold voltage of the driving sub-circuit of the abnormal sub-pixel for a compensation on the abnormal sub-pixel.

At least one embodiment of the present disclosure further provides a display substrate, the display substrate includes a display unit, the display unit is located in a display region and performs a display function, the display unit comprises a plurality of sub-pixels, and each of the plurality of sub-pixels comprises a pixel circuit; the pixel circuit comprises: a driving sub-circuit, a light-emitting element and a sensing sub-circuit, the driving sub-circuit is configured to control a magnitude of a driving current flowing through the light-emitting element; a control terminal of the sensing sub-circuit is configured to receive a sensing scan signal, a first terminal of the sensing sub-circuit is electrically connected to a first terminal of the driving sub-circuit and a first electrode of the light-emitting element; the display substrate comprises a plurality of sensing signal lines, a second terminal of the sensing sub-circuit is electrically connected to a corresponding one sensing signal line among the plurality of sensing signal lines, and the sensing sub-circuit is configured to detect an electrical characteristic of the sub-pixel to which the sensing sub-circuit belongs through the sensing signal line electrically connected thereto in respond to the received sensing scan signal; the plurality of sub-pixels in the display unit comprises a first sub-pixel, a second sub-pixel and a third sub-pixel; a second terminal of a sensing sub-circuit of the first sub-pixel and a second terminal of the sensing sub-circuit of the second sub-pixel are electrically connected to a same one sensing signal line among the plurality of sensing signal lines, a second terminal of the sensing sub-circuit of the third sub-pixel and a second terminal of the sensing sub-circuit of the first sub-pixel are respectively electrically connected to different sensing signal lines, and a control terminal of the sensing sub-circuit of the first sub-pixel and a control terminal of the sensing sub-circuit of the second sub-pixel are respectively electrically connected to different sensing scan signal terminals to receive different sensing scan signals.

At least one embodiment of the present disclosure further provides a detection method applied to any one of the above-mentioned display substrates provided by the embodiment of the present disclosure, the detection method includes: applying different sensing scan signals respectively to a control terminal of the sensing sub-circuit of the first sub-pixel and a control terminal of the sensing sub-circuit of the second sub-pixel, so that the sensing sub-circuit of the first sub-pixel and the sensing sub-circuit of the second sub-pixel are electrically turned on in different time periods; and detecting electrical signals on the same sensing signal line electrically connected to a second terminal of the sensing sub-circuit of the first sub-pixel and a second terminal of the sensing sub-circuit of the second sub-pixel respectively during the time period in which the sensing sub-circuit of the first sub-pixel is electrically turned on and during the time period in which the sensing sub-circuit of the first sub-pixel is electrically turned on.

At least one embodiment of the present disclosure further provides a display device, and the display device includes any one of the display substrates provided by the embodiments of the present disclosure.

FIG. 1 is a block diagram of a display substrate provided by at least one embodiment of the present disclosure. As shown in FIG. 1, the display substrate 10 includes a display region DR and a non-display region NR at least partially surrounding the display region DR. The display substrate 10 includes a plurality of display units PU located in the display region DR and distributed in an array. The display units PU perform display functions. Each display unit PU includes a plurality of sub-pixels 100. For example, in FIG. 1, the case that one display unit PU including three sub-pixels 100 is illustrated as an example, of course, the number of sub-pixels included in one display unit PU is not limited, and may also be less than three or more than three. Each sub-pixel 100 includes a light-emitting element and a pixel circuit that drives the light-emitting element. As shown in FIG. 1, the display substrate 10 further includes a plurality of scan lines GL and a plurality of data lines DL. A plurality of scan lines GL and a plurality of data lines DL intersect with each other to define a plurality of pixel regions distributed in an array in the display region DR, and each pixel region is provided with a pixel circuit of one sub-pixel 100. The pixel circuit is, for example, a conventional pixel circuit, such as a nTmC (n and m are positive integers) pixel circuit, such as a 3T1C (i.e., two transistors and one capacitor) pixel circuit, 4T2C pixel circuit, 5T1C pixel circuit, or the like, and in different embodiments, the pixel circuit may further include a compensation sub-circuit, which may include an internal compensation sub-circuit or an external compensation sub-circuit. The compensation sub-circuit may include transistor(s), capacitor(s), etc. For example, according to the requirement, the pixel circuit may further include a reset circuit, a light-emitting control sub-circuit, a detection circuit, etc. For example, the display substrate 10 may further include a scan driving circuit SC and a data driving circuit DC located in the non-display region NR. The scan driving circuit SC is, for example, a gate driving circuit (e.g., GOA driving circuit). The scan driving circuit SC is connected to the pixel circuit through the scan line GL to provide various scan signals, and the data driving circuit DC is connected to the pixel circuit through the data line DL to provide data signals. The positional relationships of the scan driving circuit SC and the data driving circuit DC, the scan lines GL and the data lines DL in the display substrate illustrated in FIG. 1 is merely an example, and the actual arrangement positions thereof can be designed as needed.

For example, the display substrate 10 may further include a control circuit (not shown). For example, the control circuit is configured to control the data driving circuit DC to apply the data signal, and to control the gate driving sub-circuit to apply the scan signal. An example of such a control circuit is a timing control circuit (T-con). The control circuit may be in various forms, for example, including a processor and a memory, the memory includes executable code, and the processor runs the executable code to perform the above detection method.

For example, the processor may be a central processing unit (CPU) or a processing device in other forms with data processing capability and/or instruction execution capability, and may include, for example, a microprocessor, a programmable logic controller (PLC), or the like.

For example, a memory device may include one or more computer program products, which may include various forms of computer-readable storage medium, such as volatile memory and/or non-volatile memory. Volatile memory may include, for example, random access memory (RAM) and/or cache memory (cache), etc. Non-volatile memory may include, for example, read-only memory (ROM), hard disk, flash memory, etc. One or more computer program instructions may be stored on the computer-readable storage medium, and the processor may execute the expected function of the program instruction. Various application programs and various data may be further stored in the computer-readable storage medium.

As needed, the pixel circuit may include a driving sub-circuit, a data writing sub-circuit, a compensation sub-circuit and a storage sub-circuit, and may also include a light-emitting control sub-circuit, a reset circuit, etc. as needed.

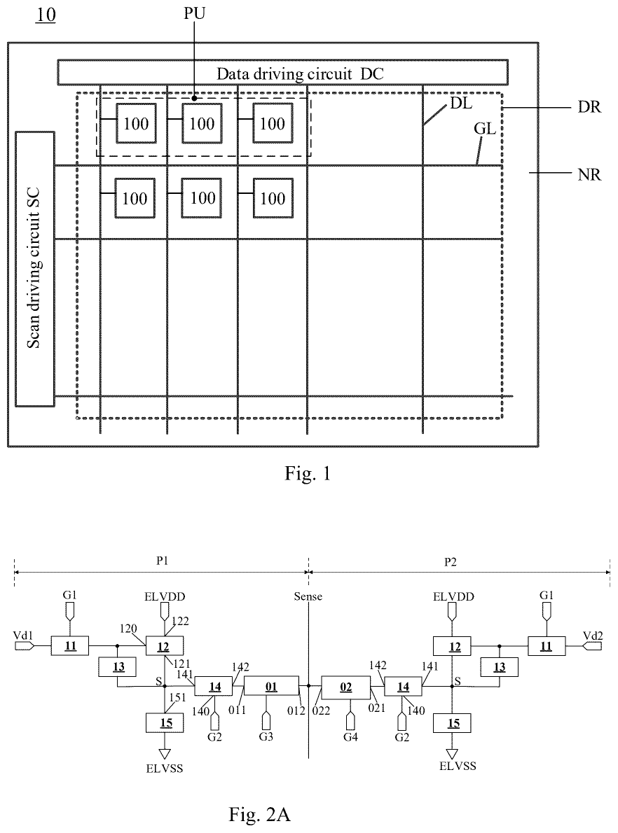

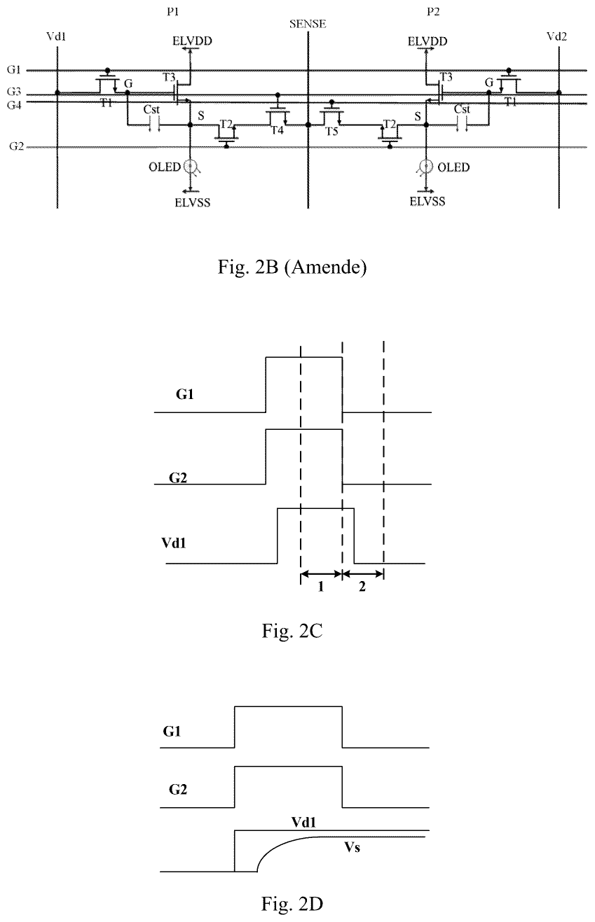

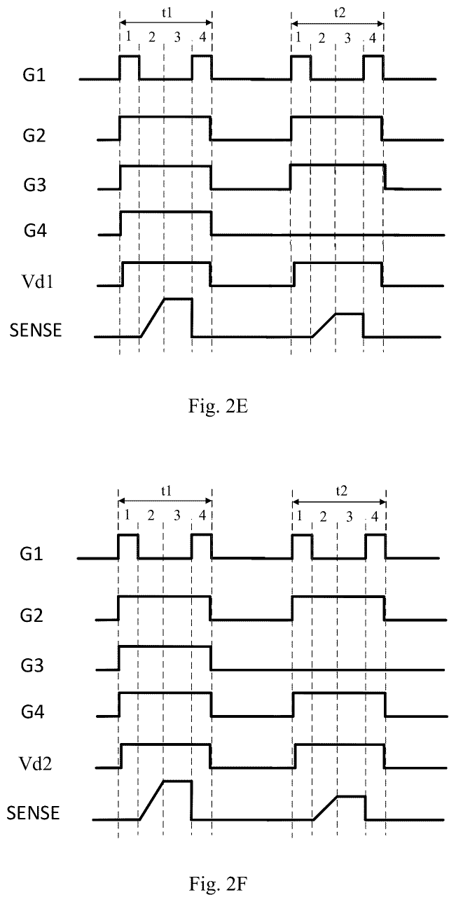

FIG. 2A illustrates a schematic block diagram of a pixel circuit of a display unit provided by at least one embodiment of the present disclosure. As shown in FIG. 2A, the pixel circuit includes: a driving sub-circuit 12, a light-emitting element 15 and a sensing sub-circuit 14. The driving sub-circuit 12 is configured to control the magnitude of the driving current flowing through the light-emitting element 15; in each sub-pixel including the pixel circuit, a control terminal of the sensing sub-circuit 14 is electrically connected to a sensing scan signal line to receive a sensing scan signal G2, and a first terminal 141 of the sensing sub-circuit 14 is electrically connected to a first terminal of the driving sub-circuit 12 and a first electrode 151 of the light-emitting element 15; the display substrate 10 includes a sensing signal line SENSE, a sensing scan signal line and a detection scan signal line. For example, the plurality of scan lines GL include the sensing signal line and the detection scan signal line. The sensing sub-circuit 14 is configured to detect the electrical characteristic of the sub-pixel 100 to which the sensing sub-circuit 14 belongs through the sensing signal line SENSE in response to the sensing scan signal G2. For example, the control terminals of the sensing sub-circuits 14 of the plurality of sub-pixels 100 of the display unit PU are electrically connected to the same one sensing scan signal line to receive the same sensing scan signal G2.

Among the plurality of sub-pixels 100 of the display unit PU, the pixel circuit of at least one sub-pixel 100 includes a detection control sub-circuit, and a control terminal of the detection control sub-circuit is electrically connected to the detection scan signal line to receive a detection scan signal G2. A first terminal of the detection control sub-circuit is electrically connected to the second terminal of the sensing sub-circuit, and a second terminal of the detection control sub-circuit is electrically connected to the sensing signal line SENSE. For illustration, in FIG. 2A, one display unit PU includes two sub-pixels 100, which are the first sub-pixel P1 and the second sub-pixel P2 respectively. Taking the first sub-pixel P1 as an example, for example, the first sub-pixel P1 includes a first detection control sub-circuit 01, and the detection scan signal lines includes a first detection scan signal line. In the first sub-pixel P1, a control terminal of the first detection control sub-circuit 01 is electrically connected to the first detection scan signal line to receive a first detection scan signal G3, and a first terminal 011 of the first detection control sub-circuit 01 is electrically connected to a second terminal 142 of the sensing sub-circuit 14, and a second terminal 012 of the first detection control sub-circuit 01 is electrically connected to the sensing signal line SENSE.

For example, the plurality of sub-pixels 100 of the display unit PU respectively include a plurality of detection control sub-circuits as mentioned above. For example, the plurality of detection control sub-circuits included in the plurality of sub-pixels in the display unit PU are electrically connected to the same one sensing signal line SENSE, and the control terminals of the plurality of detection control sub-circuits are respectively connected to different detection scan signal lines. In this case, the plurality of sub-pixels 100 share one sensing signal line SENSE.

For example, as shown in FIG. 2A, the second sub-pixel P2 also includes a detection control sub-circuit, that is, the second sub-pixel P2 includes a second detection control sub-circuit 02; the detection scan signal lines further includes a second detection scan signal line, a control terminal of the second detection control sub-circuit 02 is electrically connected to the second detection scan signal line to receive a second detection scan signal G4, and a first terminal 011 of the first detection control sub-circuit 01 is electrically connected to the second terminal 142 of the sensing sub-circuit 14, and a second terminal 012 of the first detection control sub-circuit 01 is electrically connected to the sensing signal line SENSE. For example, as illustrated in FIG. 2A, the pixel circuit of the first sub-pixel P1 includes the first detection control sub-circuit 01, and the second terminal 142 of the sensing sub-circuit 14 of the first sub-pixel Pl is electrically connected to the sensing signal line SENSE through the first detection control sub-circuit 01; the pixel circuit of the second sub-pixel P2 includes a second detection control sub-circuit 02, and the second terminal 142 of the sensing sub-circuit 14 of the second sub-pixel P2 is electrically connected to the sensing signal line SENSE through the second detection control sub-circuit 02, and the second terminal 012 of the first detection control sub-circuit 01 and the second terminal 022 of the second detection control sub-circuit 02 are electrically connected to the same one sensing signal line SENSE.

The electrical characteristic of the sub-pixel 100 includes, for example, the threshold voltage and/or carrier mobility of the driving transistor (described below) included in the driving sub-circuit 12, or the threshold voltage, driving current of the light-emitting element included in the driving sub-circuit 12, etc.

In the pixel circuits of the display unit PU, the first sub-pixel Pl and the second sub-pixel P2 share the same one sensing signal line SENSE. In the process of detecting the electrical signals on the sensing signal line SENSE, the first sub-pixel P1 and the second sub-pixel P2 are respectively detected through controlling whether turning on the first detection control sub-circuit 01 and the second detection control sub-circuit 02, so as to respectively obtain an electrical signal from the first sub-pixel P1 and an electrical signal from the second sub-pixel P2, and avoid interference caused by superposition of the electrical signal of the first sub-pixel and the electrical signal of the second sub-pixel, so as to determine whether the sensing sub-circuit 14 of the first sub-pixel P1 and the sensing sub-circuit 14 of the second sub-pixel P2 are abnormal respectively, and determine the abnormal sub-pixel or sub-pixel column, thereby solving the abnormal problem of the sub-pixel or sub-pixel column in a targeted manner.

For example, the control terminal of the first detection control sub-circuit 01 is configured to receive the first detection scan signal G3, and the first terminal 011 of the first detection control sub-circuit 01 is electrically connected to the second terminal 142 of the sensing sub-circuit 14 of the first sub-pixel P1, and the second terminal 012 of the first detection control sub-circuit 01 is electrically connected to the sensing signal line SENSE; the control terminal of the first detection control sub-circuit 01 is configured to receive the second detection scan signal G4, and the first terminal 021 of the second detection control sub-circuit 02 is electrically connected to the second terminal 142 of the sensing sub-circuit 14 of the second sub-pixel P2, and the second terminal 022 of the second detection control sub-circuit 02 is electrically connected to the sensing signal line SENSE. The second scan signal G4 and the first scan signal G3 may be different. For example, the second scan signal G4 and the first scan signal G3 respectively come from different scan signal lines and can be controlled independently of each other. Therefore, whether the first detection control sub-circuit 01 and the second detection control sub-circuit 02 are electrically turned on can be independently controlled by controlling the first detection scan signal G3 and the second detection scan signal G4, respectively. In response to the first detection control sub-circuit 01 being electrically turned on, the electrical signal passing through the sensing sub-circuit 14 of the first sub-pixel P1 is allowed to reach the sensing signal line SENSE through the first detection control sub-circuit 01, otherwise this electrical signal is not allowed to reach the sensing signal line SENSE. In response to the second detection control sub-circuit 02 being electrically turned on, the electrical signal passing through the sensing sub-circuit 14 of the second sub-pixel P2 is allowed to reach the sensing signal line SENSE through the second detection control sub-circuit 02, otherwise this electrical signal is not allowed to reach the sensing signal line SENSE.

For example, as shown in FIG. 2A, the pixel circuit further includes a data writing sub-circuit 11 and a storage sub-circuit 13. A first terminal of the storage sub-circuit 13 is electrically connected to a driving end 120 of the driving sub-circuit 12, and a second terminal of the storage sub-circuit 13 is electrically connected to the first electrode 151 of the light-emitting element 15. The second electrode of the light-emitting element 15 receives, for example, a second power supply voltage ELVSS. The data writing sub-circuit 11 is configured to write a data signal Vd1 (taking the first sub-pixel as an example, data signals in the second sub-pixel, the third sub-pixel and the fourth sub-pixel are respectively labeled as Vd2, Vd3 and Vd4) into a control terminal of the driving sub-circuit 12 in response to the data scan signal G1, and the driving sub-circuit 12 is configured to control the magnitude of the driving current flowing through the light-emitting element 15 according to the data signal.

FIG. 2B is a circuit diagram of an implementation example of the pixel circuit illustrated in FIG. 2A. As shown in FIG. 2B, for example, the storage sub-circuit 13 includes a storage capacitor Cst, and the driving sub-circuit 12 includes a driving transistor T3. The gate electrode of the driving transistor T3 is electrically connected to the first electrode of the storage capacitor Cst, the first electrode of the driving transistor T3 is electrically connected to the second electrode of the storage capacitor Cst, and is electrically connected to the light-emitting element 15, and the second electrode of the driving transistor T3 is configured to receive a first power supply voltage ELVDD, and the driving transistor T3 is configured to control the current for driving the light-emitting element 15 under the control of the voltage of the gate electrode of the driving transistor T3. For example, the sensing sub-circuit 14 includes a sensing transistor T2, the first electrode of the sensing transistor T2 is electrically connected to the first electrode of the driving transistor T3 and the second terminal of the storage sub-circuit 13, and the second electrode of the sensing transistor T2 is electrically connected to the sensing signal line SENSE, the sensing signal line SENSE is electrically connected to the detection circuit, the gate electrode of the sensing transistor T2 is configured to receive the sensing scan signal G2, and the sensing transistor T2 is configured to detect the electrical characteristic of the sub-pixel 100 to which the sensing transistor T2 belongs through the detection circuit in response to the sensing scan signal G2, so as to realize electrical compensation. The electrical characteristic includes, for example, the threshold voltage and/or carrier mobility of the driving transistor T3, or the threshold voltage and driving current of the light-emitting element, etc., and is described taking the case that the electrical characteristic is the threshold voltage of the driving transistor T3 as an example here. The detection circuit may be, for example, an external detection circuit of the pixel circuit, that is, the sensing signal line SENSE is connected to an external detection circuit to detect the electrical signal on the sensing signal line SENSE. For example, the detection circuit is a conventional circuit including a digital-to-analog converter (DAC), and an analog-to-digital converter (ADC), etc., which will not be described in detail in the embodiment of the present disclosure.

For example, in a sub-pixel having the detection control transistor, the second electrode of the detection control transistor is electrically connected to the sensing signal line, and the gate electrode of the detection control transistor is electrically connected to a corresponding detection scan signal line.

Still referring to FIG. 2B, for example, the first detection control sub-circuit 01 includes a first detection control transistor T4, the gate electrode of the first detection control transistor T4 is configured to receive the first detection scan signal G3, the first electrode of the first detection control transistor T4 is electrically connected to the second electrode of the sensing transistor T2 of the first sub-pixel P1, and the second electrode of the first detection control transistor T4 is electrically connected to the sensing signal line SENSE; the second detection control sub-circuit 02 includes a second detection control transistor T5, the gate electrode of the second detection control transistor T5 is configured to receive the second detection scan signal G4, the first electrode of the second detection control transistor T5 is electrically connected to the second electrode of the sensing transistor T2 of the second sub-pixel P2, and the second electrode of the second detection control transistor T5 is electrically connected to the sensing signal line SENSE, that is, the second electrode of the first detection control transistor T4 and the second electrode of the second detection control transistor T5 are electrically connected to the same one sensing signal line SENSE. The gate electrode of the first detection control transistor T4 is electrically connected to the first detection scan signal line to receive the first detection scan signal G3, and the gate electrode of the second detection control transistor T5 is electrically connected to the second detection scan signal line to receive the second detection scan signal G4. Therefore, whether the first detection control transistor T4 and the second detection control transistor T5 are turned on can be independently controlled by controlling the first detection scan signal G3 and the second detection scan signal G4. In response to the first detection control transistor T4 being turned on, the electrical signal passing through the sensing transistor T2 of the first sub-pixel P1 is allowed to reach the sensing signal line SENSE through the first detection control transistor T4 and can be detected, and in response to the first detection control transistor T4 being turned off, this electrical signal is not allowed to reach the sensing signal line SENSE; in response to the second detection control transistor T5 being turned on, the electrical signal passing through the sensing transistor T2 of the second sub-pixel P2 is allowed to reach the sensing signal line SENSE through the second detection control transistor T5, and in response to the second detection control transistor T5 being turned off, this electrical signal is not allowed to reach the sensing signal line SENSE.

The transistors used in the embodiments of the disclosure may be thin film transistors, field effect transistors, or other switching devices with the same characteristics. In the embodiments of the disclosure, thin film transistors are used as examples for description. A source electrode and a drain electrode of the transistor used herein may be symmetrical in structure, so there may be no structural difference between the source electrode and the drain electrode. In the embodiments of the present disclosure, in order to distinguish the two electrodes of the transistor other than the gate electrode, it is directly described that one of the source and drain electrodes is the first electrode, and the other one of the source and drain electrodes is the second electrode. That is, the first electrode of the transistor may be the source electrode, and the second electrode of the transistor may be the drain electrode, alternatively, the first electrode of the transistor is the drain electrode, and the second electrode of the transistor is the source electrode. In addition, transistors can be divided into N-type and P-type transistors according to their characteristics. In the case that the transistor is a P-type transistor, the turn-on voltage is a low-level voltage (for example, 0V,-5V, −10V or other suitable voltages), and the turn-off voltage is a high-level voltage (for example, 5V, 10V or other suitable voltages); in the case that the transistor is an N-type transistor, the turn-on voltage is a high-level voltage (for example, 5V, 10V or other suitable voltages), and the turn-off voltage is a low-level voltage (for example, 0V, −5V, −10V or other suitable voltages). It should be noted that, in the following description, the transistors in the pixel circuit are N-type transistors as an example, but this is not intended to limit the present disclosure.

The working principle of the pixel circuit of one sub-pixel illustrated in FIG. 2B will be described below in conjunction with the signal timing diagrams illustrated in FIG. 2C to FIG. 2E, FIG. 2B illustrates the signal timing diagram of the pixel circuit during the display process, FIG. 2C and FIG. 2D illustrate signal timing diagrams of the pixel circuit in the process of detecting the electrical characteristic (e.g., threshold voltage) of the driving transistor T3.

For example, as illustrated in FIG. 2C, the display process of each frame of image includes a data writing and reset stage 1 and a light-emitting stage 2. FIG. 2C illustrates the timing waveforms of respective signals in each stage. A working process of the pixel circuit includes the following stages:

In the data writing and reset stage 1, the data scan signal G1 and the sensing scan signal G2 are both turn-on signals, the data transistor T1 and the sensing transistor T2 are turned on, and the data signal Vd1 is transmitted to the gate electrode of the driving transistor T3 through the data transistor T1; at the same time, the first detection scan signal G3 is a turn-on signal, the first detection control transistor T4 is turned on, and the detection circuit (such as an external detection circuit connected to the sensing signal line SENSE) writes a reset signal to the first electrode 151 of the light-emitting element 15 (such as an anode of an OLED) through the sensing signal line SENSE, the first detection control transistor T4 and the sensing transistor T2, the driving transistor T3 is turned on and generates a driving current to charge the first electrode 151 of the light-emitting element 15 to an operating voltage;

In the light-emitting stage 2, the data scan signal G1 and the sensing scan signal G2 are both turn-off signals. Due to the bootstrap effect of the storage capacitor Cst, the voltages at two ends of the storage capacitor Cst remain unchanged, and the driving transistor T3 operates in a saturated state and drives the light-emitting element to emit light; at the same time, in the light-emitting stage 2, the first detection scan signal G3 is a turn-off signal, so that the first detection control transistor T4 remains turned off. The operating processes of the pixel circuits of the respective sub-pixels during the display process are similar, and all can refer to the above description taking the first sub-pixel P1 as an example. For the first detection control transistor T4 and the second detection control transistor T5, similar to the first sub-pixel P1, in the data writing and reset stage 1 of the second sub-pixel P2, the second detection scan signal G4 is turn-on signal, and the second detection control transistor T5 is turned on; in the light-emitting stage 2 of the second sub-pixel P2, the second detection scan signal G4 is a turn-off signal, so that the second detection control transistor T5 remains turned off.

For example, FIG. 2D illustrates a signal timing diagram when performing threshold voltage detection of the driving transistor T3 in the case that the pixel circuit does not have the first detection control transistor T4. For example, the process of detecting the threshold voltage may be performed in the case where the display device is turned off. One working process of the pixel circuit includes the following stages:

The data scan signal G1 and the sensing scan signal G2 are both turn-on signals, the data transistor T1 and the sensing transistor T2 are turned on, and the data signal Vd1 is transmitted to the gate electrode of the driving transistor T3 through the data transistor T1; the detection circuit writes a reset signal to the first electrode 151 (node S) of the light-emitting element 15 through the sensing signal line SENSE and the sensing transistor T2, the driving transistor T3 is turned on and charges the node S until the driving transistor T3 is turned off, for example, the threshold voltage of the driving transistor T3 can thus be obtained using the digital to analog converter in the detection circuit to detect and sample the voltage signal on the sensing signal line SENSE. The measured threshold voltage is recorded and the pixel circuit of the corresponding sub-pixel is compensated according to the threshold voltage. For example, the threshold voltage can be added to the data signal Vd of the pixel circuit, and the data signal Vd is the data voltage, thereby realizing the compensation of driving transistor T3.

During the process of detecting and sampling the voltage on the sensing signal line SENSE, the electrical signal of the node S needs to be transmitted to the sensing signal line SENSE through the sensing transistor T2. Therefore, if an abnormality occurs to the sensing transistor T2 of the sub-pixel, for example, a short circuit occurs between the gate electrode and the source electrode or between the gate electrode and the drain electrode of the sensing transistor T2, it will cause the actual measured voltage of the node S to deviate from the actual voltage, and the threshold voltage of the driving transistor will be incorrectly determined to be larger, resulting in incorrect compensation, and the sub-pixel or the sub-pixel column in which the sub-pixel is located will be caused to be incorrectly compensated, thereby causing abnormal display problems on the display panel using the display substrate.

For the display substrate 10 provided by the embodiment of the present disclosure, abnormality detection can be performed on the sub-pixels to detect abnormal sub-pixels, for example, abnormality detection is performed on the sub-pixels column by column. For example, when a problem occurs, abnormality detection is performed on the sub-pixel column near the position with abnormal display, one column of sub-pixels shares the sensing signal line SENSE illustrated in FIG. 1B-FIG. 1C.

For example, the detection method of a display substrate provided by at least one embodiment of the present disclosure includes: performing at least two times of detections on at least one sub-pixel of a display unit PU, and performing two times of detections on the electrical signals of the sensing signal line, in one detection, the detection control transistors of all sub-pixels included in the display unit are turned on, if the electrical signal on the sensing signal line is abnormal, the next detection is performed; in the next detection, the detection control transistor of at least one sub-pixel in the display unit is turned off, so as to detect other sub-pixels again; and determines whether the plurality of sub-pixels are abnormal based on the electrical signals on the sensing signal line obtained by the two times of detections. For example, for an abnormal sub-pixel, the threshold voltage of the driving sub-circuit of the sub-pixel with the same color and without abnormality in other display units is obtained and used as the threshold voltage of the driving sub-circuit of the abnormal sub-pixel for the compensation of the abnormal sub-pixel.

In this way, an abnormal sub-pixel in a plurality of sub-pixels of the display unit can be detected, and the abnormal sub-pixel can be correctly compensated during the display process, thereby solving the above-mentioned problem that threshold voltage of the sub-pixel driving sub-circuit is incorrectly detected due to abnormality occurred to the sensing sub-circuit of the sub-pixel. For example, the threshold voltage of the driving sub-circuit of a normal sub-pixel column closest to the abnormal sub-pixel is selected and used as the above-mentioned normal threshold voltage, so as to reduce the impact on the display effect. For example, the threshold voltage of the driving sub-circuit of the sub-pixel column adjacent to the abnormal sub-pixel is obtained and used as the above-mentioned normal threshold voltage to reduce the impact on the display effect. If the sensing transistor of the adjacent sub-pixel column is also abnormal, the threshold voltage of the driving sub-circuit of the next sub-pixel column is selected and used as the above-mentioned normal threshold voltage.

It is uniformly explained that, in the present disclosure, “detection” refers to the detection on the electrical signal of the sensing signal line SENSE.

For example, specifically, taking the above-mentioned two times of detections as an example, the detection method includes the follows: during the first detection, the detection control transistors of all the sub-pixels included in the display unit PU are turned on, and a first detection is performed on the electrical signal on the sensing signal line SENSE, that is, the sub-pixels contained in the display unit are detected as a whole, if the detected signal is abnormal (the detected signal is obviously too high), then at least one sub-pixel in the display unit PU has a short circuit in the sensing transistor; in this case, in the second detection, the detection control transistor(s) of at least one sub-pixel in the display unit PU is randomly turned off, and one sub-pixel whose detection control transistor is not turned off is used as the test sub-pixel, so as to perform the second detection on the electrical signal on the sensing signal line SENSE, and to determine the abnormal sub-pixel in the display unit PU; in the second detection, if the detection signal of the sensing signal line is abnormal (for example, the detected signal is obviously too high), it indicates that, other sub-pixel(s) except the sub-pixel whose detection control transistor is turned off have the problem of short-circuit in the sensing transistor, including the case that the test sub-pixel is abnormal, and also including the case that another sub-pixel except the test sub-pixel and including the case that the sub-pixel whose detection control transistor is turned off is abnormal. If the measured detection signal of the sensing signal line is normal, it indicates that a sub-pixel whose detection control transistor is turned off has the short circuit problem in the sensing transistor.

For example, detecting a certain sub-pixel refers that: using a certain sub-pixel 100 among the plurality of sub-pixels 100 in the display unit PU as a test sub-pixel to detect the electrical signals on the sensing signal line SENSE for two times, that is, performing two times of detection on at least one sub-pixel 100 of the display unit PU includes: using at least one sub-pixel among the plurality of sub-pixels 100 in the display unit PU as the test sub-pixel to detect electrical signals on the sensing signal line SENSE for two times, during the two detection processes, the data signal is written to the test sub-pixel and the data signal is not written to other sub-pixels 100 except the test sub-pixel, for example, the data signal written to the sub-pixels 100 except the test sub-pixel is a voltage signal of 0V. In this way, during the two detection processes, in the test sub-pixel, the storage capacitor Cst is charged through the data signal, thereby charging the node S, in the case that no abnormality occurs to the sub-pixel, when the sensing transistor of the test sub-pixel is normal, the electrical potential of the node S can be transmitted to the corresponding sensing signal line SENSE through the sensing transistor and corresponding detection transistor (e.g., the first detection control transistor T4) and detected as a normal threshold voltage, if short circuit is occurred to the sensing transistor of the test sub-pixel, the voltage signal detected on the sensing signal line SENSE will be too large; for other sub-pixels in the display unit except the test sub-pixel, the written data signal is a voltage signal of 0V, if the detection transistor T2 of the sub-pixel is normal, and in the case that the corresponding detection transistor such as the first detection control transistor T4 is turned on, no voltage signal is transmitted from the node S to the corresponding sensing signal line SENSE, in the embodiment illustrated in FIG. 2B, since the sensing signal line SENSE in FIG. 2B is shared by the first sub-pixel P1 and the second sub-pixel P2, in this case, only the electrical signal from the node S of the test sub-pixel arrives the common sensing signal line SENSE and is detected, therefore, in this case, it is possible to prevent the case where the detection result is the superposition of signals from the nodes S of both the first sub-pixel P1 and the second sub-pixel P2 that are electrically connected to the same one sensing signal line SENSE, if the sensing transistor T2 of this sub-pixel is short-circuited, even if the written data signal is a voltage signal of 0V, in response to the corresponding detection transistor, such as the first detection control transistor T4, being turned on, there will also be a short-circuit electrical signal transmitted to the corresponding sensing signal line SENSE.

For example, in the process of performing two times of detections on the electrical signals of the sensing signal line SENSE using at least one sub-pixel among the plurality of sub-pixels in the display unit PU as the test sub-pixel, the two detection processes are controlled such that the first detection scan signal and the second detection scan signal in the first detection are not completely the same as the first detection scan signal and the second detection scan signal in the second detection.

In the case that the first sub-pixel P1 includes the first detection control sub-circuit 01, and the second pixel P2 includes the second detection control sub-circuit 02, when abnormality detection is performed on the sub-pixels of the display substrate 10, the detection method includes: applying a first detection scan signal G3 to the first detection control sub-circuit 01, and allowing, by the first detection control sub-circuit 01, the electrical signal of the second terminal 142 of the sensing sub-circuit 14 of the first sub-pixel P1 to be transmitted to the sensing signal line SENSE in response to the first detection scan signal G3, and detecting the electrical signal on the sensing signal line SENSE; and applying a second detection scan signal G4 to the second detection control sub-circuit 02, and allowing, by the second detection control sub-circuit 02, the electrical signal of the second terminal 142 of the sensing sub-circuit 14 of the second sub-pixel P2 to be transmitted to the sensing signal line SENSE in response to the second detection scan signal G4, and detecting the electrical signal on the sensing signal line SENSE.

The detection method of the display substrate 10 provided by the embodiment of the present disclosure includes: respectively using different sub-pixels that need to be detected (such as the first sub-pixel P1 and the second sub-pixel P2) as the test sub-pixel to perform the two times of detections, in the first detection, the detection control transistors of all the sub-pixels included in the display unit PU are turned on, the electrical signals of the nodes S of the plurality of sub-pixels electrically connected to the same one sensing signal line are allowed to be transmitted to the same one sensing signal line, while in the second detection, the detection control transistor of at least one sub-pixel in the display unit PU is turned off, thereby the electrical signal of the node S of the sub-pixel whose detection control transistor is turned off is not allowed to be transmitted to the same one sensing signal line. The sequence of these two detections can be interchanged.

For example, the detection method includes: sequentially using each sub-pixel among all the sub-pixels in the display unit PU as the test sub-pixel to perform the above-mentioned two times of detections on the electrical signal of the sensing signal line, and determining the sub-pixel with short-circuited sensing transistor according to the results of the two times of detections.

For example, the detection method of the display substrate 10 provided by the embodiment of the present disclosure further includes: obtaining the threshold voltage of the driving transistor T3 of the sub-pixel of the same color without abnormality in other display units PU as the normal threshold voltage, and using the normal threshold voltage as the threshold voltage of the driving transistor T3 of the abnormal sub-pixel to perform compensation on the abnormal sub-pixel during the display process.

For example, the display substrate 10 includes a plurality of sub-pixel columns extending along the extending direction of the sensing signal line SENSE in FIG. 2B, each sub-pixel column includes a plurality of sub-pixels, for example, among the plurality of sub-pixels included in the sub-pixel column where the first sub-pixel P1 is located, the pixel circuit of each sub-pixel is the same as the pixel circuit of the first sub-pixel P1. Taking the detection of one sub-pixel as an example to introduce the detection method, for example, when performing abnormality detection on the display substrate 10, the sub-pixels may be detected one by one, and the normal threshold voltage of the driving transistor T3 of a sub-pixel of the same color without abnormality in other display units PU is used as the threshold voltage of the sub-pixel to perform compensation on the sub-pixel; alternatively, the detection is performed column by column, and a column of sub-pixels are detected at the same time, the threshold voltages of the driving transistors T3 of a plurality of sub-pixels in an abnormal sub-pixel column are replaced as a whole with the threshold voltage of the driving transistor T3 of the normal sub-pixel column of the same color, that is, one column of sub-pixels is detected each time, and the above-mentioned replacing signal is also to replace signals of one column of sub-pixels, so as to accurate to a certain column of sub-pixels in a pixel array.

Next, a method of performing abnormality detection on a display substrate is introduced with respect to the pixel circuits of sub-pixels of several different display units provided by embodiments of the present disclosure.

For example, the plurality of sub-pixels in the display unit include a first sub-pixel and a second sub-pixel, the first sub-pixel includes a first detection control transistor, and the second sub-pixel includes a second detection control transistor, and the detection method includes the following steps:
during the first detection, both the first detection control transistor and the second detection control transistor are turned on, in response to the detection signal of the sensing signal line being abnormal, the first detection control transistor or the second detection control transistor is randomly turned off, and then the second detection is performed using the sub-pixel whose detection control transistor is not turned off as the test sub-pixel; and
during the second detection, if the detection signal of the sensing signal line is abnormal, it indicates that the sensing transistor of the test sub-pixel is abnormal; if the detection signal of the sensing signal line is normal, it indicates that the sensing transistor of another sub-pixel except the test sub-pixel is abnormal.

Illustratively, the above detection method will be described in detail by taking the detection of the pixel circuit illustrated in FIG. 2B as an example. For example, FIG. 2E to FIG. 2F are examples of signal timing diagrams when detecting abnormalities in the pixel circuit illustrated in FIG. 2B. Referring to FIG. 2E, for example, the detection method for the display substrate illustrated in FIG. 2B includes: using the first sub-pixel P1 as a test sub-pixel, and detecting the electrical signal on the sensing signal line SENSE twice, during the two times of detections, the first detection scan signals G3 are all on signals, and the second detection scan signals G4 are respectively an on signal and an off signal. t1 represents the first detection, and t2 represents the second detection.

For example, referring to FIG. 2E, the first detection includes the following 4 stages.

1. In the first stage, that is, the data writing stage, the data scan signal G1, the sensing scan signal G2, the first detection scan signal G3, and the second detection scan signal G4 are at a high potential at the same time, the data transistor T1, the sensing transistor T2, the driving transistor T3, the first detection control transistor T4 and the second detection control transistor T5 are all turned on, and a data signal Vd1 (e.g., a data voltage signal) and a reset signal (e.g., a reset voltage signal) are written to the first sub-pixel P1 respectively, which can be referred to the previous description with respect to the data writing stage and the reset stage for details, at the same time, a data signal of 0V is written to the remaining sub-pixels of the display unit except the first sub-pixel P1.

2. In the second stage, that is, the charging stage, the data scan signal G1 is at a low potential, the sensing scan signal G2, the first detection scan signal G3, and the second detection scan signal G4 are at a high potential at the same time, the data transistor T1 is turned off, the sensing transistor T2, the first detection control transistor T4, the second detection control transistor T5 and the driving transistor T3 are all turned on to charge the node S, in this case, the sensing signal line SENSE is floating (that is, not connecting to electrical signal).

3. In the third stage, that is, the sampling stage, in response to the node S being charged until the driving transistor T3 is cut off, the voltage on the sensing signal line SENSE is sampled through the ADC electrically connected to the sensing signal line SENSE, and the node S potential is measured, the measured node S potential is recorded as the first detection result.

4. In the fourth stage, that is, the reset stage, the data scan signal G1, the sensing scan signal G2, the first detection scan signal G3 and the second detection scan signal G4 are at high potential at the same time, the data transistor T1 and the sensing transistor T2 are both turned on and written with the data signal Vd1 and the reset signal respectively. For example, in some embodiments, the fourth stage may not be included in the first detection and the second detection, which is the same for the detection processes of several other kinds of pixel circuits, and will not be repeated later.

For example, in the embodiments of the present disclosure, during the abnormality detection process of the display substrate, each detection may include the above four stages, that is, the data writing stage, the charging stage, the sampling stage and the reset stage, or include the above first to third stages, that is, excluding the reset stage, which will not be repeated below. Moreover, in the embodiments of the present disclosure, in the two times of detections performed using each sub-pixel as a test sub-pixel, the order of the first detection and the second detection can be interchanged; the order of detections respectively using the respective sub-pixels as test sub-pixels can also be interchanged, the embodiment of the present disclosure does not limit the order of which sub-pixels are used as test sub-pixels. In this regard, description will not be repeated in the following embodiments.

Referring to FIG. 2E, the second detection also includes four stages, and the second detection differs from the first detection in that, the second detection scan signal G4 always maintains a low potential, so that the first detection control transistor T4 remains off, and thus the potential at node S of sub-pixel P1 cannot reach the sensing signal line SENSE, in the third stage, the voltage on the sensing signal line SENSE is sampled and recorded as the second detection result. As illustrated in FIG. 2E, if the first detection result is not equal to the second detection result, or even the voltage signal of the first detection result is significantly higher than the voltage signal of the second detection result, that is, the first detection result is abnormal, the second detection result is normal, which proves that in the first detection, the potential transmitted to the sensing signal line SENSE through the sensing transistor T2 of the first sub-pixel P1 is too high, and the sensing transistor T2 is short-circuited, that is, it is detected that the first sub-pixel Pl is abnormal, then, the threshold voltage of the driving transistor T3 of sub-pixel with the same color as the first sub-pixel P1 and without abnormality in another display unit PU is obtained as the normal threshold voltage, and the normal threshold voltage is used as the threshold voltage of the driving transistor T3 of the first sub-pixel P1 to perform compensation on the first sub-pixel P1 during the display process. If both the first detection result and second detection result are abnormal (the electrical signal is too large), it proves that there is no short circuit problem in the sensing transistor T2 of the first sub-pixel P1, and the sensing transistor T2 of the second sub-pixel P2 is short-circuited.

Referring to FIG. 2F, the detection method of the display substrate illustrated in FIG. 2B further includes: using the second sub-pixel P2 as a test sub-pixel, and performing two times of detections on the electrical signals on the sensing signal line SENSE, the two times of detections differ from the above-mentioned detections using the first sub-pixel P1 as the test sub-pixel in that, in the two detections, the second detection scan signals G4 are both on signals, and the first detection scan signals G3 are respectively an on signal and an off signal respectively. Similarly, if the first detection result is not basically equal to the second detection result, or even the voltage signal of the first detection result is significantly higher than the voltage signal of the second detection result, it proves that in the first detection, the potential transmitted to the sensing signal line SENSE through the sensing transistor T2 of the second sub-pixel P2 is too high, then there is a high probability that the sensing transistor T2 is short-circuited, that is, it is detected that the second sub-pixel P2 is abnormal, then, the threshold voltage of a driving transistor T3 of a sub-pixel with the same color as the second sub-pixel P2 and without abnormality in another display unit PU is obtained as the normal threshold voltage, and the normal threshold voltage is used as the threshold voltage of the driving transistor T3 of the second sub-pixel P2 to perform compensation on the second sub-pixel P2 during the display process. If the first detection result and the second detection result are not basically equal, it proves that the second sub-pixel P2 is normal, at least there is no short circuit problem.

It should be noted that, the order of the detection using the first sub-pixel P1 as the test sub-pixel and the detection using the second sub-pixel P2 as the test sub-pixel can be interchanged, and the order of these two steps is not limited.

For example, on the basis that the display unit includes the above-mentioned first sub-pixel and the second sub-pixel, the plurality of sub-pixels in the display unit further includes a third sub-pixel, and a second terminal of a sensing sub-circuit of the third sub-pixel is electrically connected to the same sensing signal line through the first detection control sub-circuit, during the first detection, detection control transistors of all sub-pixels included in the display unit (i.e., the first sub-pixel, the second sub-pixel and the third sub-pixel) are turned on, and a first detection is performed on the electrical signal on the sensing signal line, that is, the sub-pixels contained in the display unit are detected as a whole, if the detected signal is abnormal (the detected signal is obviously too high), then at least one sub-pixel in the display unit has a sensing transistor being short-circuited; in this case, in the second detection, the detection control transistor of at least one sub-pixel in the display unit is randomly turned off, and the second detection is performed on the electrical signal on the same sensing signal line using one sub-pixel whose detection control transistor is not turned off as the test sub-pixel, so as to determine the abnormal sub-pixel in the display unit; in the second detection, if the detected detection signal on the sensing signal line is abnormal (for example, the detected signal is obviously too high), it indicates that another sub-pixel except the sub-pixel whose detection control transistor is turned off has the problem of sensing transistor being short-circuited, including that case that the test sub-pixel is abnormal, and also including the case that another sub-pixel except the test sub-pixel and the sub-pixel whose detection control transistor is turned off is abnormal, if the detected detection signal of the sensing signal line is normal, it indicates that at least one sub-pixel whose detection control transistor is turned off has the short circuit problem in the sensing transistor.

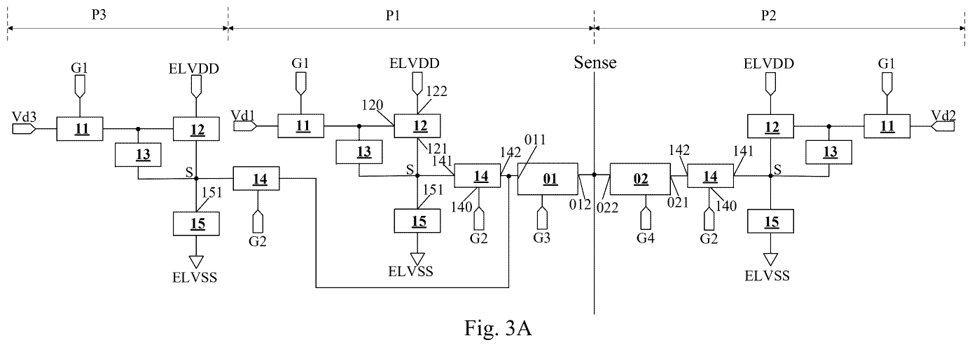

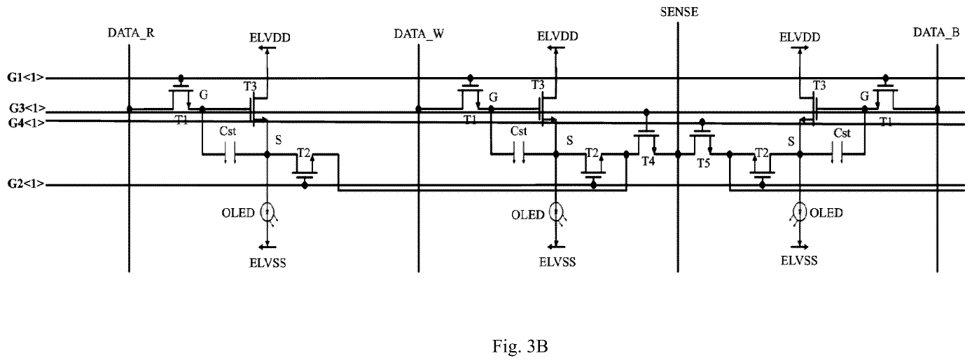

Illustratively, FIG. 3A is a schematic block diagram of a pixel circuit of another display unit provided by at least one embodiment of the present disclosure; FIG. 3B is a circuit diagram of an implementation example of the pixel circuit illustrated in FIG. 3A. The structures of the first sub-pixel P1 and the second sub-pixel P2 of the display unit illustrated in FIG. 3A are the same as those in FIG. 2A, the pixel circuit of the display unit illustrated in FIG. 3A has the following difference from the embodiment illustrated in FIG. 2A. Referring to FIG. 3A, for example, the plurality of sub-pixels 100 of the display unit PU further include a third sub-pixel P3, and the second terminal 142 of the sensing sub-circuit 14 of the third sub-pixel P3 is electrically connected to the sensing signal line SENSE through the first detection control sub-circuit 01. In this embodiment, the first sub-pixel P1, the second sub-pixel P2 and the third sub-pixel P3 share one sensing signal line SENSE. For example, the second terminal 142 of the sensing sub-circuit 14 of the third sub-pixel P3 is electrically connected to the first terminal 011 of the first detection control sub-circuit 01. In this way, in the case that there has three sub-pixels, whether the three sub-pixels are abnormal can be detected. For example, these three sub-pixels have the same connection relation of the data sub-circuit 11, the driving sub-circuit 12, the storage sub-circuit 13, the sensing sub-circuit 14 and light-emitting element 15, which can be referred to the description with respect to the previous embodiments.

For example, the 3T1C circuit structures of the three sub-pixels in FIG. 3B are the same, and can be referred to the description in FIG. 2B. Referring to FIG. 3B, a second electrode of the sensing transistor T2 of the third sub-pixel P3 is electrically connected to a second electrode of the sensing transistor T2 of the first sub-pixel P1 and a first electrode of the first detection control transistor T4 of the first sub-pixel P1.

For example, the detection method of the display panel illustrated in FIG. 3B has the following difference from the detection method of the display substrate illustrated in FIG. 2B.

The detection method for the display substrate illustrated in FIG. 3B includes: performing two times of detections on the electrical signals on the sensing signal line SENSE using at least one of the first sub-pixel P1 and the third sub-pixel P3 as a test sub-pixel, in the two times of detections, the first detection scan signals G3 are both on signals, and the second detection scan signals G4 are an on signal and an off signal respectively.

For example, the first sub-pixel P1 is used as a test sub-pixel to detect electrical signals on the sensing signal line SENSE twice. In the first detection, the first detection scan signal G3 and the second detection scan signal G4 are both turn-on signals, so that the first detection control transistor T4 and the second detection control transistor T5 are both turned on, and then in the sampling stage, the voltage on the sensing signal line SENSE in sampled, and potential at the node S is detected, the detected potential at node S is recorded as the first detection result; in the second detection, the first detection scan signal G3 is a turn-on signal, and the second detection scan signal G4 is a turn-off signal, so that the first detection control transistor T4 is turned on and the second detection control transistor T5 is turned off, then, in the sampling stage, the voltage on the sensing signal line SENSE is sampled, and the potential at the node S is detected, the detected potential at the node S is recorded as the second detection result. What is detected in the first detection is the electrical signal of the node S of the first sub-pixel P1, and what is detected in the second detection is the potential of the node S of the second sub-pixel. If the first detection result is not equal to the second detection result, or even the voltage signal of the first test result is significantly higher than that of the second test result, that is, the first test result is abnormal and the second test result is normal, then it proves that in the first detection, the potential transmitted to the sensing signal line SENSE through the sensing transistor T2 of the second sub-pixel P2 is too high, which proves that the sensing transistor T2 of the second sub-pixel P2 is short-circuited, that is, it is detected that the second sub-pixel P2 is abnormal, then, the threshold voltage of a driving transistor T3 of a sub-pixel with the same color as the second sub-pixel P2 and without abnormality in another display unit PU is obtained and used as the threshold voltage of the driving transistor T3 of the second sub-pixel P2 to perform compensation on the second sub-pixel P2 during the display process. If both the first detection result and the second detection result are abnormal (the electrical signal is too large), it proves that the second sub-pixel P2 does not have a short-circuit problem in the sensing transistor T2, and both the first sub-pixel P1 and the third sub-pixel P3 are possible to have the short-circuit problem in their sensing transistors T2, this is because that no matter whether the first sub-pixel P1 or the third sub-pixel P3 has a short-circuit problem in the sensing transistor T2, there will have excessive short-circuit signal from the corresponding sensing transistor T2 being transmitted to the sensing signal line SENSE through the turned-on first detection control transistor T4. Of course, the third sub-pixel P3 may also be used as a test sub-pixel to perform the two detections, the method of determining the abnormal sub-pixel based on the two detection results is the same as the above-mentioned determining method of using the first sub-pixel Pl as a test sub-pixel to perform the two detections, the principles thereof are the same.

The detection method for the display substrate illustrated in FIG. 3B further includes: using the second sub-pixel P2 as a test sub-pixel to detect the electrical signals on the sensing signal line SENSE twice, in the two times of detections, the second detection scan signals G4 are both on signals, and the first detection scan signals G3 are an on signal and an off signal, respectively. For example, in the first detection, the first detection scan signal G3 and the second detection scan signal G4 are both turn-on signals, so that the first detection control transistor T4 and the second detection control transistor T5 are both turned on, and then in the sampling stage, the voltage on the sensing signal line SENSE is sampled and the potential at node S potential is detected, the detected potential at node S is recorded as a first detection result; in the second detection, the first detection scan signal G3 is a turn-off signal, the second detection scan signal G4 is a turn-on signal, so that the first detection control transistor T4 is turned off, and the second detection control transistor T5 is turned on, and then the voltage on the sensing signal line SENSE is sampled during the sampling stage, and the potential at the node S is detected, the detected potential at node S is recorded as a second detection result. If the first detection result is not equal to the second detection result, or even the voltage signal of the first detection result is significantly higher than the voltage signal of the second detection result, it proves that in the first detection, the potential transmitted to the sensing signal line SENSE through the sensing transistor(s) T2 of the first sub-pixel P1 and/or of the third sub-pixel P3 is too high, then there is a high probability that the sensing transistor T2 of the first sub-pixel P1 and/or the sensing transistor T2 of the third sub-pixel P3 are short-circuited, that is, it is detected that the first sub-pixel Pl and/or the third sub-pixel P3 are abnormal, then the threshold voltages of driving transistors T3 of sub-pixels with the same color as the first sub-pixel P1 and the third sub-pixel P3 and without abnormality in other display units PU are obtained and used as the threshold voltages of the driving transistors T3 of the first sub-pixel P1 and the third sub-pixel P3 to perform compensation on the first sub-pixel P1 and the third sub-pixel P3 during the display process, respectively. If the first detection result is substantially equal to the second detection result, it proves that the first sub-pixel P1 and the third sub-pixel P3 are normal, and at least there is no short circuit problem in these two sub-pixels. In this way, abnormal sub-pixels among multiple sub-pixels of the display unit can be detected, and the abnormal sub-pixels can be correctly compensated during the display process, thus solving the above-mentioned problem in which the threshold voltage of the driving transistor T3 of a sub-pixel is incorrectly detected due to abnormality occurred to the sensing transistor T2 of the sub-pixel.

For each detection, the working states of other transistors in each sub-pixel except the first detection control transistor T4 and the second detection control transistor T5 at the respective stages can be referred to the description of FIG. 2E.

For example, on the basis that the display unit includes the first sub-pixel and the second sub-pixel, in the case that the plurality of sub-pixels in the display unit further include a third sub-pixel, and the pixel circuit of the third sub-pixel further includes a third detection control sub-circuit, the detection scan signal line includes a third detection scan signal line, a control terminal of the third detection control sub-circuit is electrically connected to the third detection scan signal line to receive the third detection scan signal, a first terminal of the third detection control sub-circuit is electrically connected to the second terminal of the sensing sub-circuit of the third sub-pixel, and a second terminal of the third detection control sub-circuit is electrically connected to the sensing signal line,
the detection method includes:
using one sub-pixel of the display unit as the test sub-pixel, to detect the electrical signals on the sensing signal line twice,

In the first detection, the detection control transistors of all sub-pixels included in the display unit are turned on, and a first detection is performed on the electrical signal on the sensing signal line, if the detection signal of the sensing signal line that is detected is abnormal, it indicates that at least one sub-pixel in the display unit has a short-circuit problem in the sensing transistor, and then the detection control transistors of the two sub-pixels in the display unit except the test sub-pixel are turned off, and a second detection is performed on the electrical signal on the sensing signal line;

In the second detection, if the detected detection signal of the sensing signal line is normal, it indicates that at least one of the two sub-pixels with detection control transistors being turned off have a short circuit problem in sensing transistor, if the detected detection signal of the sensing signal line is abnormal, it indicates that there is a short circuit problem in the sensing transistor of the test sub-pixel.

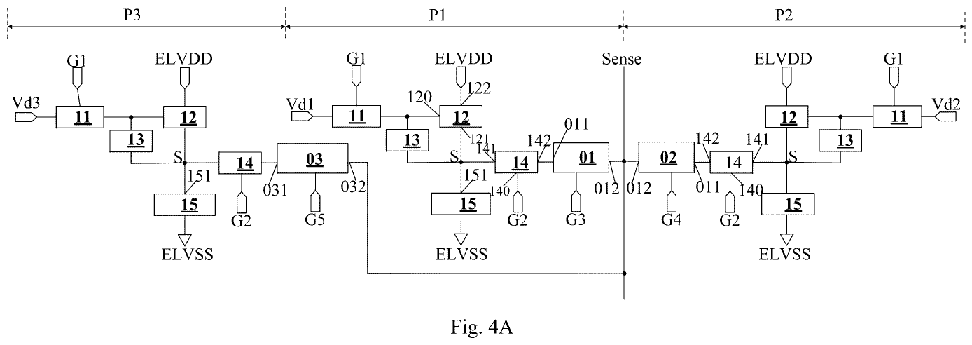

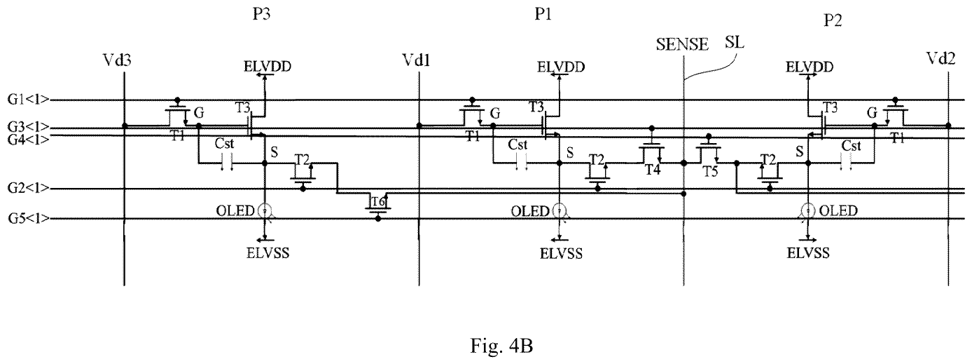

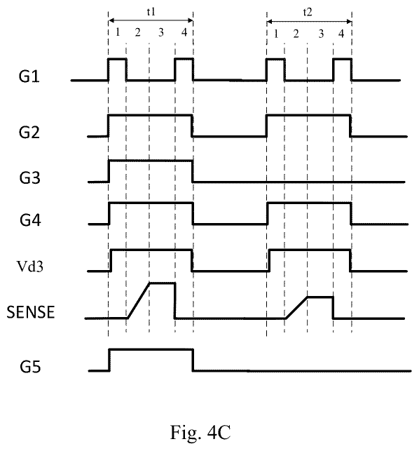

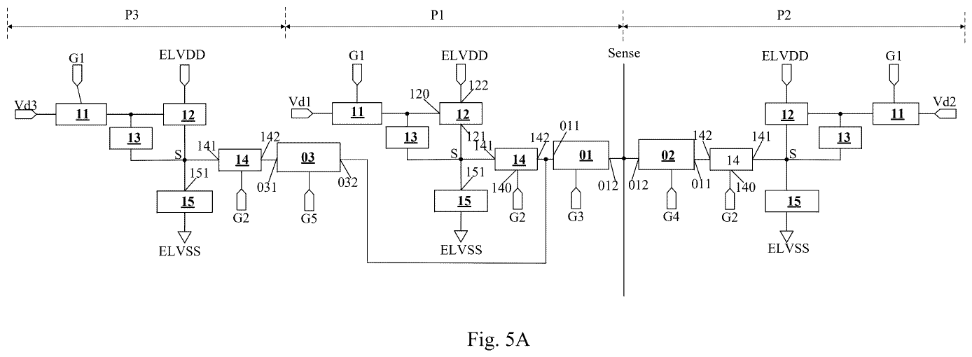

Illustratively, FIG. 4A is a schematic block diagram of a pixel circuit of another display unit provided by at least one embodiment of the present disclosure; FIG. 4B is a circuit diagram of an implementation example of the pixel circuit illustrated in FIG. 4A. The structures of the first sub-pixel P1 and the second sub-pixel P2 of the display unit illustrated in FIG. 4A are the same as those in FIG. 3A, the pixel circuits of the display unit illustrated in FIG. 4A has the following differences from the embodiment illustrated in FIG. 3A. For example, referring to FIG. 4A, the plurality of sub-pixels 100 of the display unit PU further include a third sub-pixel P3, the pixel circuit of the third sub-pixel P3 further includes a third detection control sub-circuit 03, and the second terminal 142 of the sensing sub-circuit 14 of the third sub-pixel P3 is electrically connected to the sensing signal line SENSE through the third detection control sub-circuit 03. In this embodiment, the first sub-pixel P1, the second sub-pixel P2 and the third sub-pixel P3 share one sensing signal line SENSE. For example, the detection scan signal line includes a third detection scan signal line, and the control terminal of the third detection control sub-circuit 03 is electrically connected to the third detection scan signal line to receive the third detection scan signal G5, the first terminal of the third detection control sub-circuit 03 is electrically connected to the second terminal 142 of the sensing sub-circuit 14 of the third sub-pixel P3, and the second terminal of the third detection control sub-circuit 03 is electrically connected to the sensing signal line SENSE. In the pixel circuit of the display unit provided in this embodiment, the potentials of the nodes S of the first sub-pixel P1, the second sub-pixel P2 and the third sub-pixel P3 are respectively transmitted to the sensing signal line SENSE through the first detection control sub-circuit 01, the second detection control sub-circuit 02 and the third detection control sub-circuit 03, the control of transmitting the potentials of the nodes S of the three sub-pixels to the sensing signal line SENSE are independent of each other, so that whether these three sub-pixels are abnormal can be independently detected.

Referring to FIG. 4B, for example, the third detection control sub-circuit 03 includes a third detection control transistor T6, the gate electrode of the third detection control transistor T6 is electrically connected to the third detection scan signal line to receive the third detection scan signal G5, the first electrode of the third detection control transistors T6 is electrically connected to the second electrode of the sensing transistor T2 of the third sub-pixel P3, and the second electrode of the third detection control transistor T6 is electrically connected to the sensing signal line SENSE.

For example, the detection method for the display panel illustrated in FIG. 4B has the following difference from the detection method for the display substrate illustrated in FIG. 3B. FIG. 4C is an example of a signal timing diagram when detecting an abnormality in the pixel circuit illustrated in FIG. 4B. Referring to FIG. 4C, the detection method of the display substrate illustrated in FIG. 4B includes: using the first sub-pixel P1 as a test sub-pixel to perform two times of detections on the electrical signals on the sensing signal line SENSE, during which the first detection scan signals G3 are both on signals, the second detection scan signals G4 are respectively an on signal and an off signal, and the third detection scan signals G5 are respectively an on signal and an off signal. For example, in the first detection, the first detection scan signal G3, the second detection scan signal G4 and the third detection scan signal G5 are all turn-on signals, so that the first detection control transistor T4, the second detection control transistor T5 and the third detection control transistor T6 are all turned on, and then the voltage on the sensing signal line SENSE is sampled during the sampling stage, the detected potential result is recorded as the first detection result; in the second detection, the first detection scan signal G3 is an on signal, the second detection scan signal G4 and the third detection scan signal G5 are both off signals, so that the first detection control transistor T4 is turned on, and the second detection control transistor T5 and the third detection control transistor T6 are both turned off, and then the voltage on the sensing signal line SENSE is sampled during the sampling stage, and the detected potential result is the second detection result. In the first detection, the potentials at the nodes S of the first sub-pixel P1, the second sub-pixel P2 and the third sub-pixel P3 are all transmitted to the sensing signal line SENSE, in the second detection, only the potential at the node S of the first sub-pixel P1 is transmitted to the sensing signal line SENSE. Therefore, if the first detection result is not equal to the second detection result, for example, if the voltage signal of the first detection result is obviously much higher than that of the second detection result, that is, the first detection result is abnormal, and the second detection result is normal, it proves that a short-circuit signal is transmitted to the sensing signal line SENSE in the first detection, while the second detection result is normal, it proves that the first sub-pixel P1 is normal, therefore, the second sub-pixel P2 and/or the third sub-pixel P3 are abnormal, subsequently, the second sub-pixel P2 and the third sub-pixel P3 are respectively used as test sub-pixels for detections, and whether the second sub-pixel P2 and the third sub-pixel P3 are abnormal can be detected respectively using similar methods. If the first detection result is basically the same as the second detection result and neither of them is an obviously too high voltage signal, that is, both the two detection results are normal, then these three sub-pixels are normal; if the first detection result and the second detection result are substantially equal and both are excessively high voltage signals, that is, the two detection results are both abnormal, then the first sub-pixel P1 is abnormal, and what the two detections are detected are both high short-circuit signals. Combining subsequent detections respectively using the second sub-pixel P2 and the third sub-pixel P3 as test sub-pixels, and comparing the plurality of detection results, it can be determined whether each detection result is an obviously excessively high voltage signal. Thus, it is possible to determine whether there has an abnormal sub-pixel and identify the abnormal sub-pixel.

Then, the detection method of the display substrate illustrated in FIG. 4B further includes: using the second sub-pixel P2 as a test sub-pixel to perform two times of detections on the electrical signals on the sensing signal line SENSE, during which the second detection scan signals G4 are both on signals, the first detection scan signals G3 are respectively an on signal and an off signal, and the third detection scan signals G5 are respectively an on signal and an off signal. similar to the detection using the first sub-pixel P1 as the test sub-pixel, for example, in the first detection, the first detection scan signal G3, the second detection scan signal G4 and the third detection scan signal G5 are all turn-on signals, so that the first detection control transistor T4, the second detection control transistor T5 and the third detection control transistor T6 are all turned on, and then the voltage on the sensing signal line SENSE is sampled during the sampling stage, the detected potential result is recorded as the first detection result; in the second detection, the second detection scan signal G4 is an on signal, the first detection scan signal G3 and the third detection scan signal G5 are both off signals, so that the second detection control transistor T5 is turned on, and the first detection control transistor T4 and the third detection control transistor T6 are both turned off, and then the voltage on the sensing signal line SENSE is sampled during the sampling stage, and the detected potential result is the second detection result. In the first detection, the potentials at the nodes S of the first sub-pixel P1, the second sub-pixel P2 and the third sub-pixel P3 are all transmitted to the sensing signal line SENSE, in the second detection, only the potential at the node S of the second sub-pixel P2 is transmitted to the sensing signal line SENSE. Therefore, if the first detection result is not equal to the second detection result, for example, if the voltage signal of the first detection result is obviously much higher than that of the second detection result, that is, the first detection result is abnormal, and the second detection result is normal, it proves that a short-circuit signal is transmitted to the sensing signal line SENSE in the first detection, while the second detection result is normal, it proves that the second sub-pixel P2 is normal, and at least one sub-pixel among other sub-pixels in the pixel unit PU is abnormal. If the first detection result is basically the same as the second detection result and neither of them is an obviously too high voltage signal, that is, both the two detection results are normal, then these three sub-pixels are normal; if the first detection result and the second detection result are substantially equal and both are excessively high voltage signals, that is, the two detection results are both abnormal, then the second sub-pixel P2 is abnormal, and what the two detections are detected are both high short-circuit signals. Combining the detection result of the detection using the first sub-pixel P1 as the test sub-pixel, and comparing the plurality of detection results, it can be determined whether each detection result is an obviously excessively high voltage signal. A sub-pixel with the node S signal transmitted to the sensing signal line SENSE corresponding to a significantly higher potential signal is an abnormal sub-pixel. Thus, it is possible to determine whether there has an abnormal sub-pixel and identify the abnormal sub-pixel.

For example, the detection method of the display substrate illustrated in FIG. 4B further includes: using the third sub-pixel P3 as a test sub-pixel to perform two times of detections on the electrical signals on the sensing signal line SENSE, during which the third detection scan signals G5 are both on signals, the first detection scan signals G3 are an on signal and an off signal respectively, and the second detection scan signals G4 are an on signal and an off signal respectively. whether the third sub-pixel P3 is abnormal can be detected with the principle the same as the above methods using the first sub-pixel P1 and the second sub-pixel P2 as test sub-pixels, which can be referred to the previous description. Combining the detection results respectively using the first sub-pixel P1, the second sub-pixel P2 and the third sub-pixel P3 as test sub-pixels, it can be determined whether there are abnormalities in the three sub-pixels and the abnormal sub-pixel(s) can be determined. If there is no obviously larger potential detection result in the detections respectively using the first sub-pixel P1, the second sub-pixel P2 and the third sub-pixel P3 as test sub-pixels, then these three sub-pixels are normal; if one or two sub-pixels are abnormal, the results of the two detections using the abnormal sub-pixel as the test sub-pixel are not equal, for example, the difference is large, which is the case where the two detection results have a large difference as mentioned above, as such, abnormal sub-pixel(s) can be determined according to the above method. If the three sub-pixels are all abnormal, no matter which sub-pixel is used as the test sub-pixel, the result of each detection is an obviously excessive electrical signal.

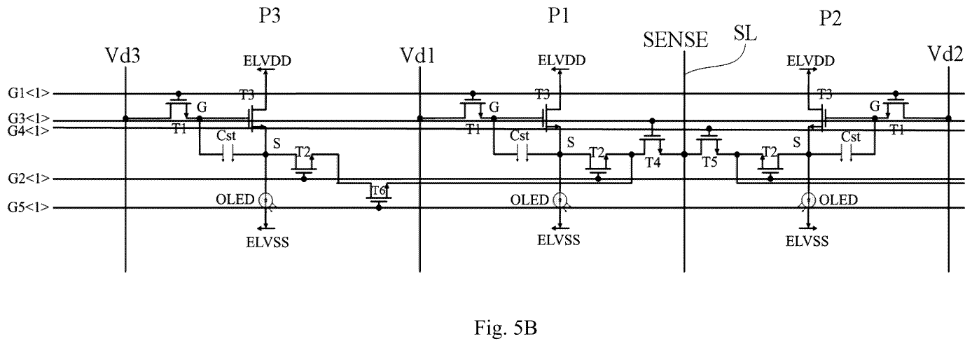

FIG. 5A is a schematic block diagram of a pixel circuit of another display unit provided by at least one embodiment of the present disclosure; FIG. 5B is a circuit diagram of an implementation example of the pixel circuit illustrated in FIG. 5A. The structures of the first sub-pixel P1 and the second sub-pixel P2 of the display unit illustrated in FIG. 5A are the same as those in FIG. 4A, the pixel circuit of the display unit illustrated in FIG. 5A has the following difference from the embodiment illustrated in FIG. 4A. For example, referring to FIG. 5A, for example, the pixel circuit of the third sub-pixel P3 further includes a third detection control sub-circuit 03, and the second terminal 142 of the sensing sub-circuit 14 of the third sub-pixel P3 is electrically connected to the sensing signal line SENSE sequentially through the third detection control sub-circuit 03 and the first detection control sub-circuit 01. In this embodiment, the first sub-pixel P1, the second sub-pixel P2 and the third sub-pixel P3 share one sensing signal line SENSE. For example, the detection scan signal line includes a third detection scan signal line, and the control terminal of the third detection control sub-circuit 03 is electrically connected to the third detection scan signal line to receive the third detection scan signal G5, the first terminal of the third detection control sub-circuit 03 is electrically connected to the second terminal 142 of the sensing sub-circuit 14 of the third sub-pixel P3, and the second terminal of the third detection control sub-circuit 03 is electrically connected to the first terminal 011 of the first detection control sub-circuit 01. The pixel circuit of the display unit can also be used to detect whether abnormalities occur to the three sub-pixels of the display unit.

Referring to FIG. 5B, for example, the third detection control sub-circuit 03 includes a third detection control transistor T6, the gate electrode of the third detection control transistor T6 is configured to receive the third detection scan signal G5, and first electrode of the third detection control transistor T6 is electrically connected to the second electrode of the sensing transistor T2 of the third sub-pixel P3, and the second electrode of the third detection control transistor T6 is electrically connected to the first electrode of the first detection control transistor T4.

For example, the detection method for the display panel illustrated in FIG. 5B has the following difference from the detection method for the display substrate illustrated in FIG. 4B. The detection method of the display substrate illustrated in FIG. 5B includes: using the first sub-pixel Pl as a test sub-pixel to perform two times of detections on the electrical signals on the sensing signal line SENSE, during which the first detection scan signals G3 are both on signals, correspondingly, the second detection scan signals G4 and the third detection scan signals G5 are respectively both on signals and both off signals. For example, in the first detection, the first detection scan signal G3, the second detection scan signal G4 and the third detection scan signal G5 are all on signals, so that the first detection control transistor T4, the second detection control transistor T5 and the third detection control transistor T6 are all turned on, and then the voltage on the sensing signal line SENSE is sampled during the sampling stage, the detected potential result is recorded as the first detection result; in the second detection, the first detection scan signal G3 is an on signal, the second detection scan signal G4 and the third detection scan signal G5 are both off signals, so that the first detection control transistor T4 is turned on, and the second detection control transistor T5 and the third detection control transistor T6 are both turned off, and then the voltage on the sensing signal line SENSE is sampled during the sampling stage, and the detected potential result is the second detection result. In the first detection, the potentials at the nodes S of the first sub-pixel P1, the second sub-pixel P2 and the third sub-pixel P3 are all transmitted to the sensing signal line SENSE, in the second detection, only the potential at the node S of the first sub-pixel P1 is transmitted to the sensing signal line SENSE. Therefore, if the first detection result is not equal to the second detection result, for example, if the voltage signal of the first detection result is obviously much higher than that of the second detection result, that is, the first detection result is abnormal, and the second detection result is normal, it proves that a short-circuit signal is transmitted to the sensing signal line SENSE in the first detection, while the second detection result is normal, it proves that the first sub-pixel P1 is normal, and the second sub-pixel P2 and/or the third sub-pixel P3 is abnormal, subsequently, the second sub-pixel P2 and the third sub-pixel P3 are respectively used as test sub-pixels for detections, and whether the second sub-pixel P2 and the third sub-pixel P3 are abnormal can be respectively detected using similar methods. If the first detection result is substantially the same as the second detection result and neither of them is an obviously too high voltage signal, that is, both the two detection results are normal, which proves that these three sub-pixels are all normal; if the first detection result is the substantially the same as the second detection result, and the two detection results are both excessively high voltage signals, what are detected in the two detections are both high short-circuit signals, that is, both detection results are abnormal, which proves that the first sub-pixel P1 is abnormal. Combining subsequent detections respectively using the second sub-pixel P2 and the third sub-pixel P3 as test sub-pixels, and comparing multiple detection results, it can be determined that whether each detection result is an obviously excessively high voltage signal. Thus, it is possible to determine whether there has an abnormal sub-pixel and identify the abnormal sub-pixel.

The detection method for the display substrate illustrated in FIG. 5B further includes: using the second sub-pixel P2 as a test sub-pixel to perform two times of detections on the electrical signals on the sensing signal line SENSE, during which the second detection scan signals G4 are both on signals, and the first detection scan signals G3 are respectively an on signal and an off signal, correspondingly, in the detection where the first detection scan signal G3 is an on signal, the third detection scan signal G5 is an on signal. For example, in the first detection, the first detection scan signal G3, the second detection scan signal G4, and the third detection scan signal G5 are all on signals, so that the first detection control transistor T4, the second detection control transistor T5 and the third detection control transistor T6 are all turned on, and then the voltage on the sensing signal line SENSE is sampled during the sampling stage, and the detected potential result is recorded as the first detection result; in the second detection, the first detection scan signal G3 is an off signal, the second detection scan signal G4 is an on signal, and the third detection scan signal G5 is an off signal or an on signal, so that the first detection control transistor T4 is turned off, the second detection control transistor T5 is turned on, and the third detection control transistor T6 is turned off or turned on (since the first detection control transistor T4 is turned off at this time, no matter whether the third detection control transistor T6 is turned off or turned on, the electrical signal in the third sub-pixel P3 will not be transmitted to the sensing signal line SENSE), and then the voltage on the sensing signal line SENSE is sampled during the sampling stage, and the detected potential result is the second detection result. In the first detection, the potentials from the nodes S of the first sub-pixel P1, the second sub-pixel P2 and the third sub-pixel P3 are all transmitted to the sensing signal line SENSE, in the second detection, only the potential of the node S of the second sub-pixel P2 is transmitted to the sensing signal line SENSE. Therefore, if the first detection result is not equal to the second detection result, for example, if the voltage signal of the first detection result is obviously much higher than that of the second detection result, that is, the first detection result is abnormal, and the second detection result is normal, it proves that there is a short-circuit signal transmitted to the sensing signal line SENSE in the first detection, while the second detection result is normal, it proves that the second sub-pixel P2 is normal, and the first sub-pixel P1 and/or the third sub-pixel P3 are abnormal, but it cannot be accurately identified whether the first sub-pixel P1 is abnormal or the third sub-pixel P3 is abnormal, in this case, threshold voltages of driving transistors T3 of sub-pixels with the same colors of the first sub-pixel P1 and the third sub-pixel P3 and without abnormality in other display units PU are obtained and used as the threshold voltages of the driving transistors T3 of the first sub-pixel P1 and the third sub-pixel P3 for performing compensation on the first sub-pixel P1 and the third sub-pixel P3 during the display process, respectively. If the first detection result and the second detection result are substantially equal and both are excessively large electrical signals, that is, both the two detection results are abnormal, it proves that the second sub-pixel P2 has a short-circuit problem in the sensing transistor T2. Thus, it is possible to determine whether there has an abnormal sub-pixel, and identify the abnormal sub-pixel, and compensation performed thereon is corrected.

The detection method for the display substrate illustrated in FIG. 5B further includes: using the third sub-pixel P3 as a test sub-pixel to perform two times of detections on the electrical signals on the sensing signal line SENSE, during which the first detection scan signals G3 and the third detection scan signals G5 are all on signals, and the second detection scan signals G4 are respectively an on signal and an off signal. For example, in the first detection, the first detection scan signal G3, the second detection scan signal G4, and the third detection scan signal G5 are all on signals, so that the first detection control transistor T4, the second detection control transistor T5 and the third detection control transistor T6 are all turned on, and then the voltage on the sensing signal line SENSE is sampled during the sampling stage, the detected potential result is recorded as the first detection result; in the second detection, the first detection scan signal G3 is an on signal, the second detection scan signal G4 is an off signal, and the third detection scan signal G5 is an on signal, so that the first detection control transistor T4 is turned on (since the first detection control transistor T4 remains on, the signal of the node S of the third sub-pixel P3 is enabled to be transmitted to the sensing signal line SENSE sequentially through the sensing transistor T2, the third detection control transistor T6 and the first detection control transistor T4 of the third sub-pixel P3), the second detection control transistor T5 is turned off, the third detection control transistor T6 is turned on, and then the voltage on the sensing signal line SENSE is sampled during the sampling stage, and the detected potential result is the second detection result. In the first detection, the potentials from the nodes S of the first sub-pixel P1, the second sub-pixel P2 and the third sub-pixel P3 are all transmitted to the sensing signal line SENSE, in the second detection, the potential of the node S of the first sub-pixel P1 and the potential of the node S of the third sub-pixel P3 are both transmitted to the sensing signal line SENSE. Therefore, in the embodiment illustrated in FIG. 5B, in the case that the first sub-pixel P1 is normal, that is, in the case that the sensing transistor T2 of the first sub-pixel P1 is not short-circuited, whether the third sub-pixel P3 is normal can be determined, that is, whether the sensing transistor T2 of the third sub-pixel P3 is short-circuited can be determined. In the case that the first sub-pixel P1 is normal, if the first detection result is not equal to the second detection result, for example, if the voltage signal of the first detection result is obviously much higher than the voltage signal of the second detection result, that is, the first detection result is abnormal and the second detection result is normal, it proves that a short-circuit signal is transmitted to the sensing signal line SENSE in the first detection, while the second detection result is normal, it proves that the first sub-pixel P1 and the third sub-pixel P3 are both normal, and the second sub-pixel P2 has a short-circuit problem in the sensing transistor T2. If the two detection results are obviously too high potential signals, that is, both detection results are abnormal, it proves that at least one of the first sub-pixel P1 and the third sub-pixel P3 is abnormal, in this case, if the first sub-pixel P1 has been determined to be normal in the previous “two detections on the electrical signals on the sensing signal line SENSE using the first sub-pixel P1 as a test sub-pixel”, then, it can be proved that the third sub-pixel P3 has a short-circuit problem in sensing transistor T2, causing that the potential on the sensing signal line SENSE to be too high, in this case, the normal threshold voltage of other sub-pixel columns with the same color as the third sub-pixel is independently used as the threshold voltage of the third sub-pixel P3 to perform display compensation on the third sub-pixel P3, without replacing the threshold voltage of the first sub-pixel P1. If the first sub-pixel Pl has been determined to be abnormal in the previous “two detections on the electrical signals on the sensing signal line SENSE using the first sub-pixel P1 as a test sub-pixel”, in the cast that the first sub-pixel Pl is abnormal, that is, in the case that the sensing transistor T2 of the first sub-pixel P1 is short-circuited, then, regardless of whether the third sub-pixel P3 is normal or not, the electrical signals transmitted to the sensing signal line SENSE through the first detection control transistor T4 are all abnormal electrical signals, therefore, in this case, whether the third sub-pixel P3 is normal or not cannot be determined, at this time, the threshold voltages of the first sub-pixel P1 and the third sub-pixel P3 are replaced at the same time, that is, threshold voltages of driving transistors T3 of sub-pixels with the same colors of the first sub-pixel P1 and the third sub-pixel P3 and without abnormality in other display units PU are obtained and used as the threshold voltages of the driving transistors T3 of the first sub-pixel P1 and the third sub-pixel P3 for performing compensation on the first sub-pixel P1 and the third sub-pixel P3 during the display process, respectively, so as to ensure that both the first sub-pixel P1 and the third sub-pixel P3 are correctly compensated.

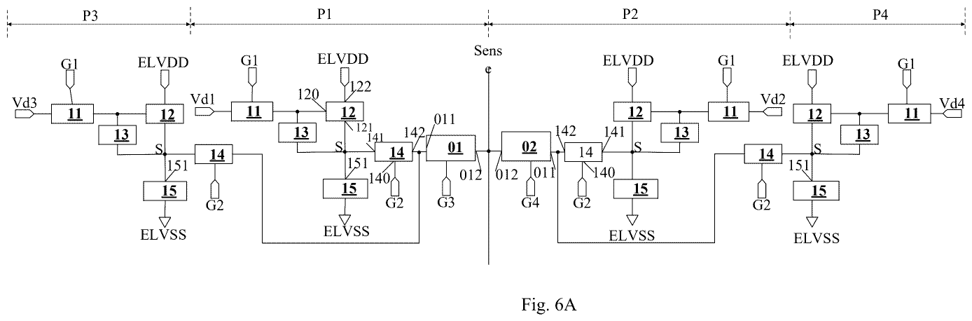

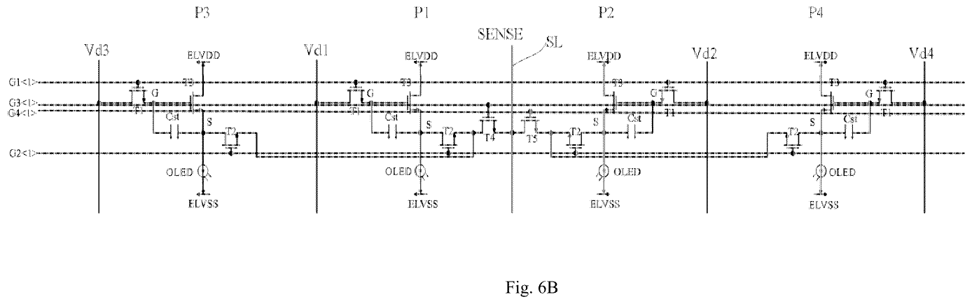

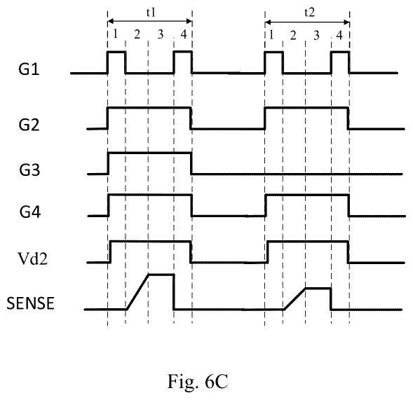

FIG. 6A is a schematic block diagram of a pixel circuit of another display unit provided by at least one embodiment of the present disclosure; FIG. 6B is a circuit diagram of an implementation example of the pixel circuit illustrated in FIG. 6A. The pixel circuit of the display unit illustrated in FIG. 6A has the following differences from the embodiment illustrated in FIG. 3A. For example, referring to FIG. 6A, the plurality of sub-pixels 100 of the display unit PU further include a fourth sub-pixel P4, and the second terminal 142 of the sensing sub-circuit 14 of the fourth sub-pixel P4 is electrically connected to the sensing signal line SENSE through the second detection control sub-circuit 02. For example, the second terminal 142 of the sensing sub-circuit 14 of the fourth sub-pixel P4 is electrically connected to the first terminal 021 of the second detection control sub-circuit 02, and the second terminal 012 of the second detection control sub-circuit 02 is electrically connected to the sensing signal line SENSE. As such, the first sub-pixel P1, the second sub-pixel P2, the third sub-pixel P3 and the fourth sub-pixel P4 share one sensing signal line SENSE. Based on a principle similar to the previous embodiments, in the case that one display unit PU includes four sub-pixels, it can be detected whether abnormalities occur in the four sub-pixels, for example, whether the sensing transistors of the four sub-pixels are short-circuited.

The detection method for the display substrate illustrated in FIG. 6B includes: using at least one of the first sub-pixel P1 and the third sub-pixel P3 as a test sub-pixel to perform two times of detections on the electrical signals on the sensing signal line SENSE, during which the first detection scan signals G3 are both on signals, and the second detection scan signals G4 are respectively an on signal and an off signal. The specific detection method is the same as the method of “using at least one of the first sub-pixel P1 and the third sub-pixel P3 as a test sub-pixel to perform two times of detections on the electrical signals on the sensing signal line SENSE” in FIG. 3B, which can be referred to the previous description.

The detection method for the display substrate illustrated in FIG. 6B further includes: using at least one of the second sub-pixel P2 and the fourth sub-pixel P4 as a test sub-pixel to perform two times of detections on the electrical signals on the sensing signal line SENSE, during which the second detection scan signals G4 are both on signals, and the fourth detection scan signals G6 are respectively an on signal and an off signal. The specific detection method of this step is similar to the method of “using at least one of the first sub-pixel P1 and the third sub-pixel P3 as the test sub-pixel”, the principles thereof are the same, except that the first sub-pixel Pl and the third sub-pixel P3 in the step of “using at least one of the first sub-pixel P1 and the third sub-pixel P3 as the test sub-pixel” are respectively replaced with the second sub-pixel P2 and the fourth sub-pixel P4, FIG. 6C is a timing taking the two detections performed using the second sub-pixel P2 as the test sub-pixel as an example. In this way, abnormal sub-pixel(s) among the four sub-pixels of the display unit can be detected, and the abnormal sub-pixel(s) can be correctly compensated during the display process.

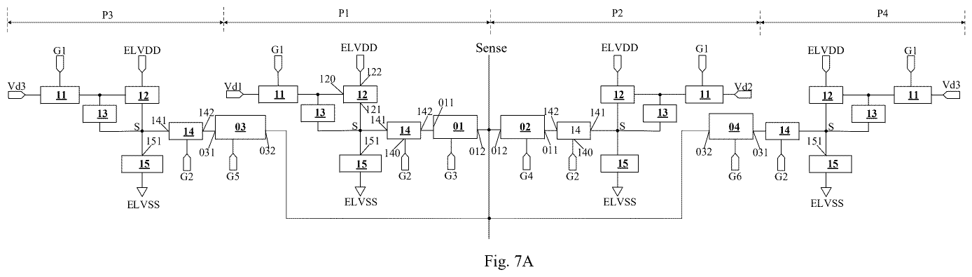

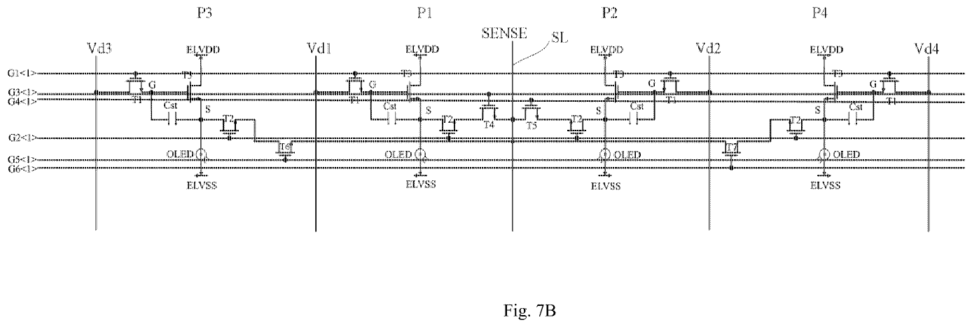

FIG. 7A is a schematic block diagram of a pixel circuit of another display unit provided by at least one embodiment of the present disclosure; FIG. 7B is a circuit diagram of an implementation example of the pixel circuit illustrated in FIG. 7A. The pixel circuit of the display unit illustrated in FIG. 7A has the following differences from the embodiment illustrated in FIG. 4A. For example, referring to FIG. 7A, for example, the plurality of sub-pixels 100 of the display unit PU further include a fourth sub-pixel P4, the pixel circuit of the fourth sub-pixel P4 further includes a fourth detection control sub-circuit 04, and the second terminal 142 of the sensing sub-circuit 14 of the fourth sub-pixel P4 is electrically connected to the sensing signal line SENSE through the fourth detection control sub-circuit 04. In this embodiment, the first sub-pixel P1, the second sub-pixel P2, the third sub-pixel P3 and the fourth sub-pixel P4 share one sensing signal line SENSE. For example, the detection scan signal line includes a fourth detection scan signal line, the control terminal of the fourth detection control sub-circuit 04 is electrically connected to the fourth detection scan signal line to receive the fourth detection scan signal G6, the first terminal of the fourth detection control sub-circuit 04 is electrically connected to the second terminal 142 of the sensing sub-circuit 14 of the fourth sub-pixel P4, and the second terminal of the fourth detection control sub-circuit 04 is electrically connected to the sensing signal line SENSE. In the pixel circuit of the display unit provided in this embodiment, the potentials of the nodes S of the first sub-pixel P1, the second sub-pixel P2, the third sub-pixel P3 and the fourth sub-pixel P4 are respectively transmitted to the sensing signal line SENSE through the first detection control sub-circuit 01, the second detection control sub-circuit 02, the third detection control sub-circuit 03 and the fourth detection control sub-circuit 04, and the control of the potentials of the nodes S of the four sub-pixels being transmitted to the sensing signal line SENSE is independent of each other, so that whether the four sub-pixels are abnormal can be independently detected.

Referring to FIG. 7B, for example, the fourth detection control sub-circuit 04 includes a fourth detection control transistor T7, a gate electrode of the fourth detection control transistor T7 is electrically connected to the fourth detection scan signal line to receive the fourth detection scan signal G6, a first electrode of the fourth detection control transistor T7 is electrically connected to the second electrode of the sensing transistor T2 of the fourth sub-pixel P4, and a second electrode of the fourth detection control transistor T7 is electrically connected to the sensing signal line SENSE.

For example, the detection method for the display substrate illustrated in FIG. 7B has the following differences from the detection method for the display substrate illustrated in FIG. 4B. The detection method of the display substrate illustrated in FIG. 7B includes: using the first sub-pixel P1 as a test sub-pixel to perform two times of detections on the electrical signals on the sensing signal line SENSE, during which the first detection scan signals G3 are both on signals, correspondingly, the second detection scan signals G4, the third detection scan signals G5 and the fourth detection scan signals G6 are each an on signal and an off signal respectively. For example, in the first detection, the first detection scan signal G3, the second detection scan signal G4, the third detection scan signal G5 and the fourth detection scan signal G6 are all on signals, so that the first detection control transistor T4, the second detection control transistor T5, the third detection control transistor T6 and the fourth detection control transistor T7 are all turned on, and then the voltage on the sensing signal line SENSE is sampled in the sampling stage, and the detected potential result is recorded as the first detection result; in the second detection, the first detection scan signal G3 is an on signal, the second detection scan signal G4, the third detection scan signal G5 and the fourth detection scan signal G6 are all off signals, so that the first detection control transistor T4 is turned on, the second detection control transistor T5, the third detection control transistor T6 and the fourth detection control transistor T7 are all turned off, and then the voltage on the sensing signal line SENSE is sampled during the sampling stage, and the detected potential result is the second detection result. In the first detection, the potentials from the nodes S of the first sub-pixel P1, the second sub-pixel P2, the third sub-pixel P3 and the fourth sub-pixel P4 are all transmitted to the sensing signal line SENSE, in the second detection, only the potential of the node S of the first sub-pixel Pl is transmitted to the sensing signal line SENSE. Therefore, if the first detection result is not equal to the second detection result, for example, if the voltage signal of the first detection result is obviously much higher than that of the second detection result, that is, the first detection result is abnormal, and the second detection result is normal, then it proves that a short-circuit signal is transmitted to the sensing signal line SENSE in the first detection, while the second detection result is normal, then it proves that the first sub-pixel P1 is normal, therefore, at least one of the second sub-pixel P2, the third sub-pixel P3 and the fourth sub-pixel P4 is abnormal, and subsequently, the second sub-pixel P2, the third sub-pixel P3 and the fourth sub-pixel P4 are respectively used as test sub-pixels for detection, and whether the second sub-pixel P2, the third sub-pixel P3 and the fourth sub-pixel P4 are abnormal can be respectively detected using similar methods. If the first detection result is substantially the same as the second detection result and neither of them is an obviously too high voltage signal, that is, both the two detection results are normal, then these three sub-pixels are normal; if the first detection result and the second detection result are substantially equal and both are excessively high voltage signals. that is, if both the two detection results are abnormal, then the first sub-pixel P1 is abnormal, and what are detected in the two detections are both high short-circuit signals. Combining with the subsequent detections respectively using the second sub-pixel P2, the third sub-pixel P3 and the fourth sub-pixel P4 as test sub-pixels, and comparing the multiple detection results, it can be determined whether each detection result is an obviously too high voltage. Thus, whether there has an abnormal sub-pixel can be determined and the abnormal sub-pixel can be identified.

The detection method for the display substrate illustrated in FIG. 7B further includes: using the second sub-pixel P2 as a test sub-pixel to perform two times of detections on the electrical signals on the sensing signal line SENSE, during which the second detection scan signals G4 are both on signals, correspondingly, the first detection scan signals G3, the third detection scan signals G5 and the fourth detection scan signals G6 are each an on signal and an off signal respectively. The principle of specific method of this step is the same as the above-mentioned method of using the first sub-pixel P1 as the test sub-pixel, which can be referred to the previous description, and whether the second sub-pixel P2 is abnormal can be determined.

The detection method for the display substrate illustrated in FIG. 7B further includes: using the fourth sub-pixel P4 as a test sub-pixel to perform two times of detections on the electrical signals on the sensing signal line SENSE, during which the fourth detection scan signals G6 are both on signals, correspondingly, the first detection scan signals G3, the second detection scan signals G4 and the third detection scan signals G5 are each an on signal and an off signal respectively. The principle of the specific method of this step is the same as the above-mentioned method of using the first sub-pixel P1 as the test sub-pixel, which can be referred to the previous description, and whether the second sub-pixel P2 is abnormal can be determined. Combining with the detection results of respectively using the first sub-pixel P1, the second sub-pixel P2, the third sub-pixel P3 and the fourth sub-pixel P4 as test sub-pixels, whether there is an abnormality in the four sub-pixels can be determined, and the abnormal sub-pixel can be determined. If in the detections respectively using the first sub-pixel P1, the second sub-pixel P2, the third sub-pixel P3 and the fourth sub-pixel P4 as test sub-pixels, there is always no significantly larger potential detection result, then these four sub-pixels are all normal; if one, two or three sub-pixels are abnormal, the results of the two detections using the abnormal sub-pixel as the test sub-pixel are not equal, for example, has big difference, that is, it is the above-mentioned case where the two detection results have big difference, so that the abnormal sub-pixel(s) can be determined according to the above-mentioned method. If all four sub-pixels are abnormal, then no matter which sub-pixel is used as the test sub-pixel, the result of each detection will be an obviously excessive larger electrical signal.

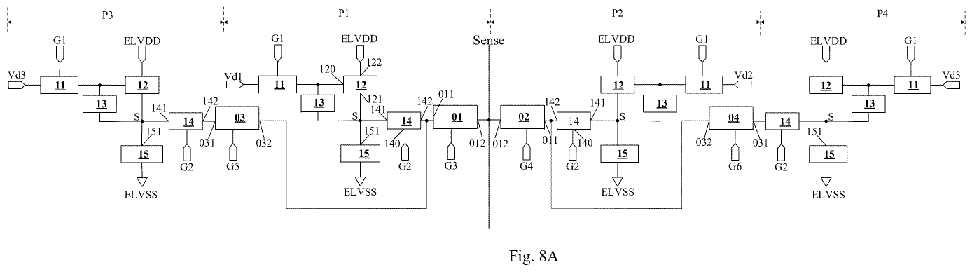

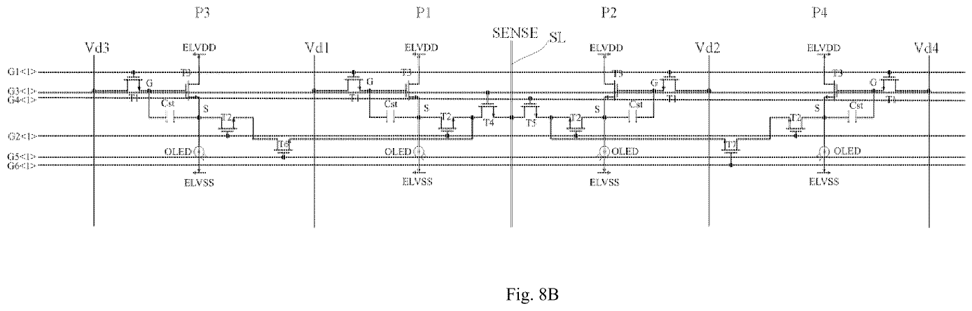

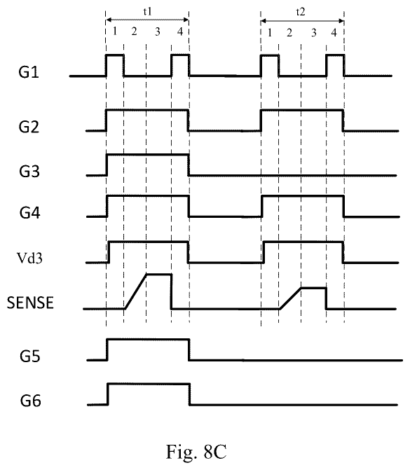

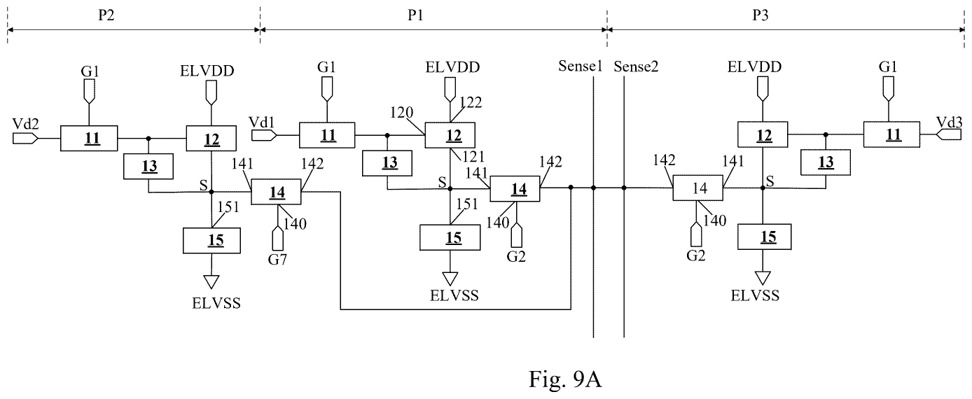

FIG. 8A is a schematic block diagram of a pixel circuit of another display unit provided by at least one embodiment of the present disclosure; FIG. 8B is a circuit diagram of an implementation example of the pixel circuit illustrated in FIG. 8A. The pixel circuit of the display unit illustrated in FIG. 8A has the following differences from the embodiment illustrated in FIG. 8A. Referring to FIG. 8A, the plurality of sub-pixels 100 of the display unit PU further include a fourth sub-pixel P4, the pixel circuit of the fourth sub-pixel P4 further includes a fourth detection control sub-circuit 04, and the second terminal 142 sensing sub-circuit 14 of the fourth sub-pixel P4 is electrically connected to the sensing signal line SENSE sequentially through the fourth detection control sub-circuit 04 and the second detection control sub-circuit 02. In this embodiment, the first sub-pixel P1, the second sub-pixel P2, the third sub-pixel P3 and the fourth sub-pixel P4 share one sensing signal line SENSE. For example, the detection scan signal line includes a fourth detection scan signal line, the control terminal of the fourth detection control sub-circuit 04 is electrically connected to the fourth detection scan signal line to receive the fourth detection scan signal G6, the first terminal of the fourth detection control sub-circuit 04 is electrically connected to the second terminal 142 of the sensing sub-circuit 14 of the fourth sub-pixel P4, and the second terminal of the fourth detection control sub-circuit 04 is electrically connected to the first terminal 021 of the second detection control sub-circuit 02. The pixel circuit of the display unit can also be used to detect whether abnormalities occur in the four sub-pixels of the display unit.

Referring to FIG. 8B, for example, the fourth detection control sub-circuit 04 includes a fourth detection control transistor T7, a gate electrode of the fourth detection control transistor T7 is configured to receive the fourth detection scan signal G6, a first electrode of the fourth detection control transistor T7 is electrically connected to the second electrode of the sensing transistor T2 of the fourth sub-pixel P4, and the second electrode of the fourth detection control transistor T7 is electrically connected to the first electrode of the second detection control transistor T5.

FIG. 8C is an example of a signal timing diagram when detecting an abnormality in the pixel circuit illustrated in FIG. 8B, FIG. 8C is a timing example of performing two times of detections using the second sub-pixel P2 illustrated in FIG. 8B as a test sub-pixel, and the timing of two detections using other sub-pixels as test sub-pixels is similar thereto, which can be understood with reference to FIG. 8C. For example, the detection method for the display panel illustrated in FIG. 8B has the following differences from the detection method for the display substrate illustrated in FIG. 5B.

The detection method for the display substrate illustrated in FIG. 8B includes: using the first sub-pixel P1 as a test sub-pixel to detect the electrical signals on the sensing signal line SENSE twice, in the two times of detections, the first detection scan signals G3 are both on signals, correspondingly, the second detection scan signals G4 and the third detection scan signals G5 are respectively on signals and off signals at the same time, in the detection that the second detection scan signal G4 is an on signal, the fourth detection scan signal G6 is an on signal. For example, in the first detection, the first detection scan signal G3, the second detection scan signal G4, the third detection scan signal G5 and the fourth detection scan signal G6 are all on signals, so that the first detection control transistor T4, the second detection control transistor T5, the third detection control transistor T6 and the fourth detection control transistor T7 are all turned on, and then the voltage on the sensing signal line SENSE is sampled in the sampling stage, and the detected potential result is recorded as the first detection result; in the second detection, the first detection scan signal G3 is an on signal, the second detection scan signal G4 and the third detection scan signal G5 are both off signals, and the fourth detection scan signal G6 is an off signal or an on signal, so that the first detection control transistor T4 is turned on, the second detection control transistor T5 is turned off, the third detection control transistor T6 is turned off, and the fourth detection control transistor T7 is turned on or turned off (at this time, since the second detection control transistor T5 is turned off, no matter whether the fourth detection control transistor T7 is turned off or turned on, the electrical signal in the fourth sub-pixel P4 will not be transmitted to the sensing signal line SENSE), and then the voltage on the sensing signal line SENSE is sampled during the sampling stage, and the detected potential result is the second detection result. In the first detection, the potentials from the nodes S of the first sub-pixel P1, the second sub-pixel P2, the third sub-pixel P3 and the fourth sub-pixel P4 are all transmitted to the sensing signal line SENSE, in the second detection, only the potential of the node S of the first sub-pixel P1 is transmitted to the sensing signal line SENSE. Therefore, if the first detection result is not equal to the second detection result, for example, if the voltage signal of the first detection result is obviously much higher than that of the second detection result, that is, the first detection result is abnormal, and the second detection result is normal, then it proves that a short-circuit signal is transmitted to the sensing signal line SENSE in the first detection, while the second detection result is normal, then it proves that the first sub-pixel P1 is normal, therefore, at least one of the second sub-pixel P2, the third sub-pixel P3 and the fourth sub-pixel P4 is abnormal, subsequently, the second sub-pixel P2, the third sub-pixel P3 and the fourth sub-pixel P4 are respectively used as test sub-pixels for detections, and whether the second sub-pixel P2, the third sub-pixel P3, and the fourth sub-pixel P4 are abnormal are respectively detected using similar methods. If the first detection result is substantially the same as the second detection result and neither of them is an obviously too high voltage signal, that is, both the two detection results are normal, then the four sub-pixels are all normal; if the first detection result and the second detection result are substantially the same and both are excessively high voltage signals, what are detected in the two detections are both high short-circuit signals, that is, if the two detection results are both abnormal, then the first sub-pixel P1 is abnormal. Combining with the subsequent detections respectively using the second sub-pixel P2, the third sub-pixel P3 and the fourth sub-pixel P4 as test sub-pixels, and comparing the multiple detection results, it can be determined whether each detection result is an obviously excessively high voltage signal. Thus, whether there is an abnormal sub-pixel can be determined and the abnormal sub-pixel can be identified.

The detection method for the display substrate illustrated in FIG. 8B further includes: using the second sub-pixel P2 as a test sub-pixel to detect the electrical signals on the sensing signal line SENSE twice, in the two times of detections, the second detection scan signals are all on signals, correspondingly, the first detection scan signals G3 and the fourth detection scan signal G6 are respectively on signals and off signals at the same time, in the detection in which the first detection scan signal G3 is an on signal, the third detection scan signal G5 is an on signal. The specific detection and determining method is similar to the above-mentioned “using the first sub-pixel P1 as a test sub-pixel to detect the electrical signals on the sensing signal line SENSE twice”, the principles thereof are the same, which can be referred to the above-mentioned principle and detection process.

Referring to FIG. 8C, the detection method of the display substrate illustrated in FIG. 8B further includes: using the third sub-pixel P3 as a test sub-pixel to detect the electrical signals on the sensing signal line SENSE twice, during the two times of detections, the first detection scan signals G3 and the third detection scan signals G5 are both on signals, correspondingly, the second detection scan signals G4 are an on signal and an off signal respectively, in the detection where the second detection scan signal G4 is an on signal, the fourth detection scan signal G6 is an on signal. For example, in the first detection, the first detection scan signal G3, the second detection scan signal G4, the third detection scan signal G5 and the fourth detection scan signal G6 are all on signals, so that the first detection control transistor T4, the second detection control transistor T5, the third detection control transistor T6 and the fourth detection control transistor T7 are all turned on, and then the voltage on the sensing signal line SENSE is sampled in the sampling stage, and the detected potential result is recorded as the first detection result; in the second detection, the first detection scan signal G3 is an on signal, the second detection scan signal G4 is an off signal, the third detection scan signal G5 is an on signal, and the fourth detection scan signal G6 is an off signal or an on signal, so that the first detection control transistor T4 is turned on (since the first detection control transistor T4 remains on, the signal of the node S of the third sub-pixel P3 can be transmitted to the sensing signal line SENSE sequentially through the sensing transistor T2, the third detection control transistor T6 and the first detection control transistor T4 of the third sub-pixel P3), the second detection control transistor T5 is turned off, the third detection control transistor T6 is turned on, and the fourth detection control transistor T7 is turned on or turned off (at this time, since the second detection control transistor T5 is turned off, no matter whether the fourth detection control transistor T7 is turned off or turned on, the electrical signal in the fourth sub-pixel P4 will not be transmitted to sensing signal line SENSE), and then the voltage on the sensing signal line SENSE is sampled during the sampling stage, and the detected potential result is the second detection result. In the first detection, the potentials from the nodes S of the first sub-pixel P1, the second sub-pixel P2, the third sub-pixel P3 and the fourth sub-pixel P4 are all transmitted to the sensing signal line SENSE, in the second detection, the potential of the node S of the first sub-pixel P1 and the potential of the node S of the third sub-pixel P3 are both transmitted to the sensing signal line SENSE. Therefore, in the embodiment illustrated in FIG. 8B, in the case that the first sub-pixel P1 is normal, that is, in the case that the sensing transistor T2 of the first sub-pixel P1 is not short-circuited, whether the third sub-pixel P3 is normal or not can be determined, that is, whether the sensing transistor T2 of the third sub-pixel P3 is short-circuited or not can be determined. In the case that the first sub-pixel P1 is normal, if the first detection result is not equal to the second detection result, for example, if the voltage signal of the first detection result is obviously much higher than that of the second detection result, that is, the first detection result is abnormal and the second detection result is normal, then it proves that a short-circuit signal is transmitted to the sensing signal line SENSE in the first detection, while the second detection result is normal, then it proves that the first sub-pixel P1 and the third sub-pixel P3 are both normal, and the second sub-pixel P2 and/or the fourth sub-pixel P4 have a short-circuit problem in the sensing transistor T2. If the two detection results are both obviously too high potential signals, that is, both detection results are abnormal, then it proves that at least one of the first sub-pixel P1 and the third sub-pixel P3 is abnormal, at this time, if the first sub-pixel P1 has been determined to be normal in the previous “two detections of the electrical signals on the sensing signal line SENSE using the first sub-pixel P1 as the test sub-pixel”, then, it can be proved that the third sub-pixel P3 has a short-circuit problem in sensing transistor T2, causing the potential on the sensing signal line SENSE to be too large, at this time, the normal threshold voltage of other sub-pixel columns with the same color as the third sub-pixel is independently used as the threshold voltage of the third sub-pixel P3 to perform display compensation on the third sub-pixel P3, without replacing the threshold voltage of the first sub-pixel P1. If the first sub-pixel P1 has been determined to be abnormal in the previous “two detections of the electrical signals on the sensing signal line SENSE using the first sub-pixel P1 as the test sub-pixel”, that is, in the case that the sensing transistor T2 of the first sub-pixel P1 is short-circuited, then, no matter whether the third sub-pixel P3 is normal or not, the electrical signal transmitted to the sensing signal line SENSE through the first detection control transistor T4 is an abnormal electrical signal, therefore, in this case, whether the third sub-pixel P3 is normal or not cannot be determined, at this time, threshold voltages of the first sub-pixel P1 and the third sub-pixel P3 are replaced at the same time, that is, threshold voltages of driving transistors T3 of sub-pixels with the same colors of the first sub-pixel P1 and the third sub-pixel P3 and without abnormality in other display units PU are obtained and used as the threshold voltages of the driving transistors T3 of the first sub-pixel P1 and the third sub-pixel P3 for performing compensation on the first sub-pixel P1 and the third sub-pixel P3 during the display process, respectively, so as to ensure that both the first sub-pixel P1 and the third sub-pixel P3 are correctly compensated.

The detection method for the display substrate illustrated in FIG. 8B further includes: using the fourth sub-pixel P4 as a test sub-pixel to detect the electrical signals on the sensing signal line SENSE twice, in the two times of detections, the second detection scan signals G4 and the fourth detection scan signals G6 are all on signals, correspondingly, the first detection scan signals G3 are an on signal and an off signal respectively, in the detection where the first detection scan signal G3 is an on signal, the third detection scan signal G5 is an on signal. The relationship between the second sub-pixel P2 and the fourth sub-pixel P4 is similar to the relationship between the first sub-pixel P1 and the third sub-pixel P3, the method of determining and replacing the threshold voltage can refer to the above-mentioned description of the specific determining method of “using the third sub-pixel P3 as a test sub-pixel to detect the electrical signals on the sensing signal line SENSE twice”, except that the first sub-pixel P1 and the third sub-pixel P3 in the process of “using the third sub-pixel P3 as a test sub-pixel to detect the electrical signals on the sensing signal line SENSE twice” are respectively replaced with the second sub-pixel P2 and the fourth sub-pixel P4. In this way, abnormal sub-pixels among a plurality of sub-pixels of the display unit can be detected, and the abnormal sub-pixels can be correctly compensated during the display process, thus solving the above-mentioned problem in which the threshold voltage of the driving transistor T3 of a sub-pixel is incorrectly detected due to abnormality occurred to the sensing transistor T2 of the sub-pixel.

For example, in the embodiment of the present disclosure, the detected potential or electrical signal on the sensing signal line SENSE is a voltage signal.

For example, for the display substrate provided by each embodiment of the present disclosure, the colors of a plurality of sub-pixels of one display unit PU are different from each other, and the color of the sub-pixel refers to the color of light emitted from the sub-pixel. For example, the above-mentioned first sub-pixel, second sub-pixel and third sub-pixel respectively emit red light, green light and blue light. For example, the above-mentioned first sub-pixel, second sub-pixel, third sub-pixel and fourth sub-pixel respectively emit white light, blue light, red light and green light.

For example, the display substrate is an organic light-emitting diode (OLED) display substrate, and each sub-pixel that performs a display function includes an OLED device, for example, the light-emitting element is an OLED device.

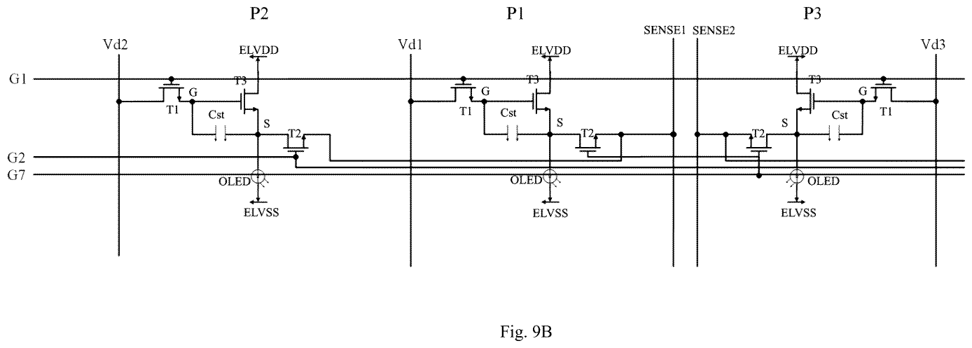

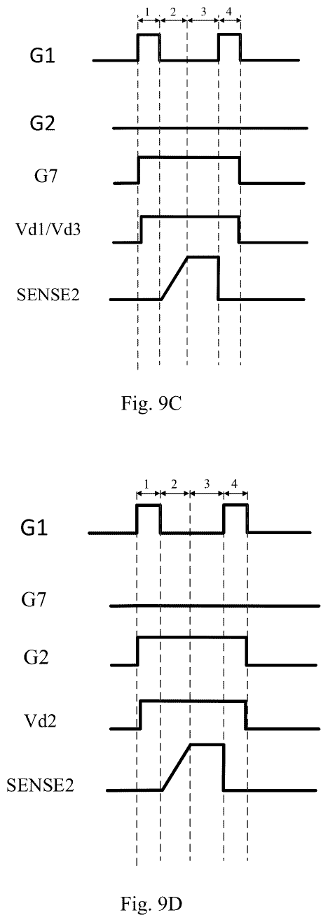

FIG. 9A is a schematic block diagram of a pixel circuit of another display unit provided by at least one embodiment of the present disclosure. The display unit, the sub-pixels, the structures such as the driving sub-circuit, the data sub-circuit, the sensing sub-circuit and the light-emitting element of each sub-pixel in the embodiment illustrated in FIG. 9A are the same as those in the previous embodiment, which can be referred to the previous description. The display substrate illustrated in FIG. 9A has the following differences from the previous embodiment.

Referring to FIG. 9A, the plurality of sub-pixels 100 of the display unit PU include a first sub-pixel P1, a second sub-pixel P2 and a third sub-pixel P3; the second terminal 142 of the sensing sub-circuit 14 of the first sub-pixel P1 and the second terminal 142 of the sensing sub-circuit 14 of the second sub-pixel P2 are electrically connected to the same one sensing signal line SENSE, for example, the second terminal 142 of the sensing sub-circuit 14 of the first sub-pixel P1 and the second terminal 142 of the sensing sub-circuit 14 of the second sub-pixel P2 are both electrically connected to a first sensing signal line SENSE; the second terminal 142 of the sensing sub-circuit 14 of the third sub-pixel P3 and the second terminal 142 of the sensing sub-circuit 14 of the first sub-pixel P1 are respectively electrically connected to different sensing signal lines SENSE, for example, the second terminal 142 of the sensing sub-circuit 14 of the third sub-pixel P3 is electrically connected to a second sensing signal line SENSE. Furthermore, the control terminal of the sensing sub-circuit 14 of the first sub-pixel P1 and the control terminal of the sensing sub-circuit 14 of the second sub-pixel P2 are respectively electrically connected to different sensing scan signal terminals to receive different sensing scan signals. The control terminal of the sensing sub-circuit 14 of the first sub-pixel P1 is configured to receive the first sensing scan signal G2, and the control terminal of the sensing sub-circuit 14 of the second sub-pixel P2 is configured to receive the second sensing scan signal G7, the second sensing scan signal G7 and the first sensing scan signal G2 are different, and are scan signals independent of each other, for example, respectively come from different scan signal lines. The sensing sub-circuit 14 of the first sub-pixel P1 is configured to detect the electrical characteristic of the first sub-pixel P1 through the first sensing signal line SENSE in response to the first sensing scan signal G2, and the sensing sub-circuit 14 of the second sub-pixel P2 is configured to detect the electrical characteristic of the second sub-pixel P2 through the first sensing signal line SENSE in response to the second sensing scan signal G7. The electrical characteristic of the sub-pixel includes, for example, the threshold voltage and/or carrier mobility of the driving transistor included in the driving sub-circuit 12, or the threshold voltage, driving current, or the like of the light-emitting element. Since the first sensing scan signal G2 and the second sensing scan signal G7 are independent of each other, whether the sensing sub-circuit 14 of the first sub-pixel P1 and the sensing sub-circuit 14 of the second sub-pixel P2 are turned on can be controlled by controlling the first sensing scan signal G2 and the second sensing scan signal G7, thereby independently controlling whether to allow the electrical signal of the second terminal 142 of the sensing sub-circuit 14 of the first sub-pixel P1, the electrical signal of the second terminal 142 of the sensing sub-circuit 14 of the second sub-pixel P2 to transmit to the first detection signal line SENSE1, while the third sub-pixel P3 and the first sub-pixel P1 are respectively connected to different sensing signal lines, the electrical signal of the second terminal 142 of the sensing sub-circuit 14 of the first sub-pixel P1 and the electrical signal of the second terminal 142 of the sensing sub-circuit 14 of the third sub-pixel P3 can be detected through different sensing signal lines, respectively, as such, whether the three sub-pixels are abnormal can be independently determined, for example, the abnormality of the sub-pixels includes whether the sensing transistor T2 is short-circuited.

For example, referring to FIG. 9A, the control terminal of the third sensing sub-circuit 14 and the control terminal of the sensing sub-circuit 14 of the first sub-pixel Pl are electrically connected to the same one sensing scan signal terminal to receive the same sensing scan signal, and are both configured to receive the second sensing scan signal G7. In this way, detecting whether the respective sub-pixels have short circuit abnormalities can be realized, meanwhile, the number of wires that provide sensing scan signals is reduced, the structure of the display substrate is simplified, the process difficulty is reduced, and the yield of display substrate product is improved.

FIG. 9B is a circuit diagram of an implementation example of the pixel circuit illustrated in FIG. 9A. Referring to FIG. 9B, for example, the second terminal of the sensing transistor T2 of the first sub-pixel P1 and the second terminal of the sensing transistor T2 of the second sub-pixel P2 are both electrically connected to the first detection signal line SENSE1, the second terminal of the sensing transistor T2 of the third sub-pixel P3 is electrically connected to the second detection signal line SENSE2; and, the gate electrode of the sensing transistor T2 of the first sub-pixel P1 and the gate electrode of the sensing transistor T2 of the second sub-pixel P2 are respectively configured to receive different sensing scan signals, for example, the gate electrode of the sensing transistor T2 of the first sub-pixel P1 is configured to receive the second sensing scan signal G7, the gate electrode of the sensing transistor T2 of the second sub-pixel P2 is respectively configured to receive the first sensing scan signal G3. For example, the gate electrode of the sensing transistor T2 of the third sub-pixel P3 is also configured to receive the second sensing scan signal G7, that is, receive the same sensing signal as the gate electrode of the sensing transistor T2 of the first sub-pixel P1. As such, whether the sensing transistor T2 of the first sub-pixel P1 and the sensing transistor T2 of the second sub-pixel P2 are turned on can be controlled through controlling the first sensing scan signal G2 and the second sensing scan signal G7, thereby independently controlling whether to allow the electrical signal of the second terminal of the sensing transistor T2 of the first sub-pixel P1, the electrical signal of the second terminal of the sensing transistor T2 of the second sub-pixel P2 to transmit to the first detection signal line SENSE1, while the third sub-pixel P3 and the first sub-pixel Pl are respectively connected to different sensing signal lines, the electrical signal of the second terminal of the sensing transistor T2 of the first sub-pixel P1 and the electrical signal of the second terminal of the sensing transistor T2 of the third sub-pixel P3 can be detected through different sensing signal lines, respectively, as such, whether the three sub-pixels are abnormal can be independently determined, for example, the abnormality of the sub-pixels includes whether the sensing transistor T2 is short-circuited.

The detection method of the display substrate illustrated in FIG. 9A includes: applying different sensing scan signals respectively to the control terminal of the sensing sub-circuit of the first sub-pixel and the control terminal of the sensing sub-circuit of the second sub-pixel, to enable the sensing sub-circuit of the first sub-pixel and the sensing sub-circuit of the second sub-pixel to be turned on during different time periods; detecting electrical signals on the same one sensing signal line that is electrically connected to the second terminal of the sensing sub-circuit of the first sub-pixel and the second terminal of the sensing sub-circuit of the second sub-pixel respectively during the period in which the sensing sub-circuit of the first sub-pixel is turned on and during the period in which the sensing sub-circuit of the first sub-pixel is turned on; and whether the first sub-pixel and the second sub-pixel are abnormal can be determined according to the electrical signals respectively detected on the sensing signal line.

The detection method of the display substrate illustrated in FIG. 9A further includes: applying the same sensing scan signal to the control terminal of the sensing sub-circuit of the first sub-pixel and the control terminal of the sensing sub-circuit of the third sub-pixel, to enable the sensing sub-circuit of the first sub-pixel and the sensing sub-circuit of the third sub-pixel to be turned on during the same time period; and respectively detecting electrical signals on different sensing signal lines respectively electrically connected to the second terminal of the sensing sub-circuit of the first sub-pixel and the second terminal of the sensing sub-circuit of the third sub-pixel during the same time period; and determining whether the first sub-pixel and the second sub-pixel are abnormal based on the detected electrical signals on the different sensing signal lines, respectively.

The detection method of the pixel circuit of the display unit illustrated in FIG. 9B is described in detail below in conjunction with the timing diagram.

FIG. 9C to FIG. 9D are examples of signal timing diagrams when detecting an abnormality in the pixel circuit illustrated in FIG. 9B. FIG. 9C is a signal timing diagram of the detection using the first sub-pixel P1 or/and the third sub-pixel P3 as the test sub-pixel. Referring to FIG. 9C, the first sub-pixel P1 and the third sub-pixel P3 can be used as test sub-pixels at the same time for detection, and the sensing signals (e.g., voltage signals) on the sensing signal lines electrically connected to the first sub-pixel P1 and the third sub-pixel P3 are respectively detected once, which can thus determine whether the test sub-pixels are abnormal and obtain the threshold voltage of the sensing transistor of the sub-pixel. The first stage is the data writing stage, the second stage is the charging stage, the third stage is the sampling stage, and the fourth stage is the reset stage, in the data writing stage, the data writing stage, the sampling stage and the reset stage, the data scan signal G1 and the corresponding working process can be referred to the foregoing description. During the entire detection process, the first sensing scan signal G2 is at low level, and is an off signal, so that the sensing transistor T2 of the second sub-pixel P2 is turned off, therefore, the electrical signal at the second terminal of the sensing transistor T2 of the second sub-pixel P2 will not be transmitted to the first detection signal line SENSE1, at the same time, the second sensing scan signal G7 is high level, and is an on signal, so that the sensing transistor T2 of the first sub-pixel P1 and the sensing transistor T2 of the third sub-pixel P3 are both turned on, so that the electrical signal at the second terminal of the sensing transistor T2 of the first sub-pixel P1 is transmitted to the first detection signal line SENSE1, and the electrical signal at the second terminal of the sensing transistor T2 of the third sub-pixel P3 is transmitted to the second detection signal line SENSE2. In this case, during the sampling stage, the voltages on the first detection signal line SENSE1 and the second detection signal line SENSE2 are sampled respectively, if the detected voltage on the corresponding detection signal line is an obviously excessive voltage signal, then the sub-pixel is abnormal, it is most likely that the sensing transistor of the sub-pixel is short-circuited, resulting in a short-circuit signal being detected, in this case, the threshold voltage of the driving transistor T3 of the sub-pixel of the same color and without abnormality in other display units PU is used as the normal threshold voltage, and the normal threshold voltage is used as the threshold voltage of the driving transistor T3 of the abnormal sub-pixel for compensation of the abnormal sub-pixel during the display process. If the detected voltage on the corresponding detection signal line is not an obviously excessive voltage signal, then the sub-pixel is normal and there is no abnormality, at least there is no short circuit problem. In the detection process, the first sub-pixel Pl and the third sub-pixel P3 can operate at the same time without interfering with each other, at the same time, they are applied with normal data signals Vd1 and Vd3 respectively, therefore, whether the first sub-pixel P1 and the third sub-pixel P3 are abnormal can be detected at the same time, thereby improving the detection efficiency, and the detection method is simple and easy to operate.

FIG. 9D is a signal timing diagram for detection using the second sub-pixel P2 as the test sub-pixel. Referring to FIG. 9D, the second sub-pixel P2 is used as the test sub-pixel for detection, during the entire detection process, the second sensing scan signal G7 is at low level, which is an off signal, so that the sensing transistor T2 of the second sub-pixel P2 is turned on, and the sensing transistor T2 of the first sub-pixel P1 and the sensing transistor T2 of the third sub-pixel P3 are both turned off, so that the electrical signal at the second terminal of the sensing transistor T2 of the second sub-pixel P2 is transmitted to the first detection signal line SENSE1, at the same time, the electrical signal at the second terminal of the sensing transistor T2 of the first sub-pixel Pl is not transmitted to the first detection signal line SENSE1. In this case, the voltage on the first detection signal line SENSE1 is sampled during the sampling stage, if the detected voltage on the first detection signal line SENSE1 is an obviously excessively large voltage signal, then the second sub-pixel P2 is abnormal, it is most likely that the sensing transistor of the second sub-pixel P2 is short-circuited, resulting in a short-circuit signal being detected, in this case, the threshold voltage of the driving transistor T3 of the sub-pixel with the same color as the second sub-pixel P2 and without abnormality in other display units PU is used as the normal threshold voltage, and the normal threshold voltage is used as the threshold voltage of the driving transistor T3 of the abnormal second sub-pixel P2 for the compensation of the abnormal second sub-pixel P2 during the display process. If the detected voltage on the first detection signal line SENSE1 is not an obviously excessively large voltage signal, then the second sub-pixel P2 is normal and there is no abnormality, at least there is no short circuit problem. In this way, the abnormal sub-pixel among multiple sub-pixels of the display unit can be detected, and the abnormal sub-pixel can be correctly compensated during the display process, thus solving the above-mentioned problem in which the threshold voltage of the driving transistor T3 of a sub-pixel is incorrectly detected due to abnormality occurred to the sensing transistor T2 of the sub-pixel, and the number of abnormal detections for the display substrate is less, the abnormal sub-pixel can be quickly determined, the detection efficiency is high, and the above-mentioned problem in which the threshold voltage of the driving transistor T3 of a sub-pixel is incorrectly detected due to abnormality occurred to the sensing transistor T2 of the sub-pixel is solved.

In the embodiment illustrated in FIG. 9B, since the gate electrode of the sensing transistor T2 of the third sub-pixel P3 and the gate electrode of the sensing transistor T2 of the first sub-pixel Pl receive the same sensing scan signal, the sensing transistor T2 of the third sub-pixel P3 and the sensing transistor T2 of the first sub-pixel P1 are turned on at the same time or turned off at the same time, therefore, in the above process of detection using the second sub-pixel P2 as the test sub-pixel, the electrical signal at the second terminal of the sensing transistor T2 of the third sub-pixel P 3 will not be transmitted to the first detection signal line SENSE2.

Of course, in other embodiments, the control terminal of the sensing sub-circuit 14 of the third sub-pixel P3 and the control terminal of the sensing sub-circuit 14 of the first sub-pixel P1 can be electrically connected to different sensing scan signal terminals for receiving different sensing scan signals, respectively. Therefore, whether the sensing sub-circuit 14 of the third sub-pixel P3 and the sensing sub-circuit 14 of the first sub-pixel P1 are turned on can be independently controlled, and abnormalities of the three sub-pixels can be independently detected. Correspondingly, in a specific implementation example of a pixel circuit including a 3T1C circuit, the gate electrode of the sensing transistor T2 of the first sub-pixel P1 and the gate electrode of the sensing transistor T2 of the third sub-pixel P3 respectively receive the same sensing scan signal. In this way, the sensing scan signals received by the sensing transistors of the three sub-pixels are different from each other, and the turn-on and turn-off of the sensing transistors of the three sub-pixels can be independently controlled by independently controlling the three different sensing scan signals respectively, so as to realize the independent detection on the voltage signal transmitted through the sensing transistor of each sub-pixel to the sensing signal line electrically connected to the sub-pixel, so as to respectively determine whether each sub-pixel is abnormal.

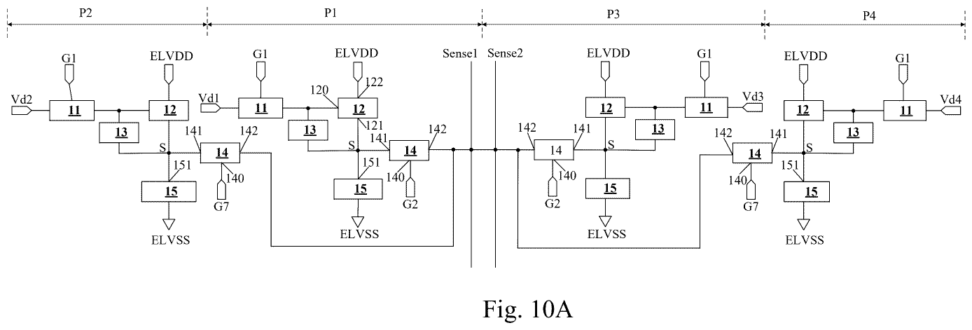

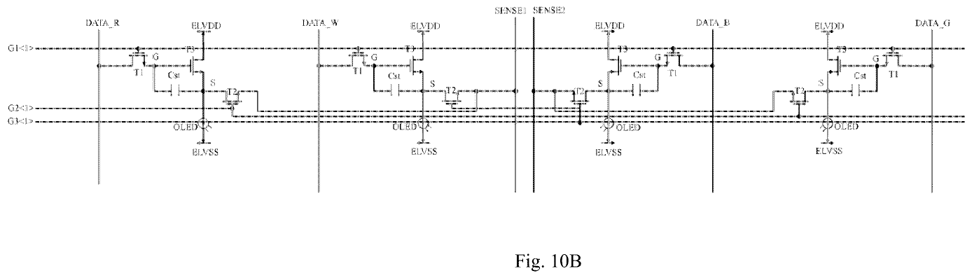

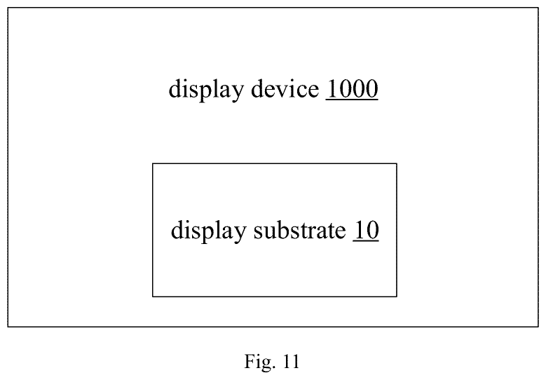

FIG. 10A is a schematic block diagram of a pixel circuit of another display unit provided by an embodiment of the present disclosure; FIG. 10B is a circuit diagram of an implementation example of the pixel circuit illustrated in FIG. 10A. The embodiment illustrated in FIG. 10A has the following differences from the embodiment illustrated in FIG. 9A. Referring to FIG. 10A, based on the pixel circuit of the display unit PU illustrated in FIG. 9B, the plurality of sub-pixels 100 of the display unit PU further include a fourth sub-pixel P4, and the second terminal 142 of the sensing sub-circuit 14 of the fourth sub-pixel P4 and the second terminal 142 of the sensing sub-circuit 14 of the third sub-pixel P3 are electrically connected to the same one sensing signal line SENSE, and the control terminal of the sensing sub-circuit 14 of the third sub-pixel P3 and the control terminal of the sensing sub-circuit 14 of the fourth sub-pixel P4 are electrically connected to different sensing scan signal terminals to receive different sensing scan signals, respectively. Therefore, as the same as the principle of the above-mentioned independent detection on whether the first sub-pixel P1 and the second sub-pixel P2 are abnormal, for the display substrate illustrated in FIG. 10A, whether the fourth sub-pixel P4 is abnormal can be independently detected, so that whether there are abnormalities in the four sub-pixels of the display unit PU can be independently detected, and the abnormal sub-pixels can be correctly compensated during the display process, at the same time, disposing multiple different sensing scan signal terminals and sensing scan signal lines can be avoided, the circuit is simplified, the difficulty of fabrication and the error rate during the fabrication process can be reduced.

For example, referring to FIG. 10B, the control terminal of the sensing sub-circuit 14 of the second sub-pixel P2 and the control terminal of the sensing sub-circuit 14 of the fourth sub-pixel P4 are electrically connected to the same sensing scan signal G2 terminal to receive the same sensing scan signal. Therefore, as the same as the above-mentioned independent detection on whether the first sub-pixel P1 and the second sub-pixel P2 are abnormal, and the abnormal sub-pixel is correctly compensated during the display process, thus solving the above-mentioned problem in which the threshold voltage of the driving transistor T3 of a sub-pixel is incorrectly detected due to abnormality occurred to the sensing transistor T2 of the sub-pixel, and the number of abnormal detections for the display substrate is less, the abnormal sub-pixel can be quickly determined, and the detection efficiency is high, which solves the above-mentioned problem in which the threshold voltage of the driving transistor T3 of a sub-pixel is incorrectly detected due to abnormality occurred to the sensing transistor T2 of the sub-pixel.

FIG. 11 is a schematic block diagram of a display device provided by an embodiment of the present disclosure. Referring to FIG. 11, at least one embodiment of the present disclosure further provides a display device 1000, the display device 1000 includes any display substrate 10 provided by the embodiments of the present disclosure. The display device may be, for example, a display panel, or may be any other product or component with a display function such as a monitor, an OLED panel, an OLED TV, an electronic paper, a mobile phone, a tablet, a laptop, a digital photo frame, a navigator, or the like.

What have been described above are only specific implementations of the present disclosure, the protection scope of the present disclosure is not limited thereto, and the protection scope of the present disclosure should be based on the protection scope of the claims.

1. A display substrate, comprising a display unit, wherein the display unit is located in a display region and performs a display function, the display unit comprises a plurality of sub-pixels, and each of the plurality of sub-pixels comprises a pixel circuit;
the pixel circuit comprises: a driving sub-circuit, a light-emitting element and a sensing sub-circuit, a first terminal of the sensing sub-circuit is electrically connected to a first terminal of the driving sub-circuit and a first electrode of the light-emitting element;
the display substrate comprises a sensing signal line, a sensing scan signal line and a detection scan signal line, a control terminal of the sensing sub-circuit is electrically connected to the sensing scan signal line, the sensing sub-circuit is configured to detect an electrical characteristic of a sub-pixel to which the sensing sub-circuit belongs through the sensing signal line, in response to a sensing scan signal;
among the plurality of sub-pixels of the display unit, a pixel circuit of at least one sub-pixel includes a detection control sub-circuit, wherein a control terminal of the detection control sub-circuit is electrically connected to the detection scan signal line to receive a detection scan signal, a first terminal of the detection control sub-circuit is electrically connected to a second terminal of the sensing sub-circuit, and a second terminal of the detection control sub-circuit is electrically connected to the sensing signal line.

2. The display substrate according to claim 1, wherein a plurality of detection control sub-circuits included in the plurality of sub-pixels in the display unit are electrically connected to a same one of the sensing signal line, and the control terminals of the plurality of detection control sub-circuits are respectively electrically connected to different ones of the sensing signal lines.

3. The display substrate according to claim 1, wherein the pixel circuit further comprises a storage sub-circuit and a data writing sub-circuit, the data writing sub-circuit is configured to write a data signal to a control terminal of the driving sub-circuit in response to a data scan signal;
the driving sub-circuit comprises a driving transistor, a gate electrode of the driving transistor is electrically connected to a first terminal of the storage sub-circuit, a first electrode of the driving transistor is electrically connected to a second terminal of the storage sub-circuit, and is electrically connected to the light-emitting element, a second electrode of the driving transistor is configured to receive a first power supply voltage, and the driving transistor is configured to control a current for driving the light-emitting element under a control of a voltage of the gate electrode of the driving transistor;
the sensing sub-circuit comprises a sensing transistor, the detection control sub-circuit comprises a detection control transistor, a gate electrode of the sensing transistor is electrically connected to the sensing scan signal line, a first electrode of the sensing transistor is electrically connected to a first electrode of the driving transistor and a second terminal of the storage sub-circuit, a second electrode of the sensing transistor is electrically connected to a first electrode of the detection control transistor, and a second electrode of the detection control transistor is electrically connected to the sensing signal line, a gate electrode of the detection control transistor is electrically connected to the detection scan signal line.

4. The display substrate according to claim 3, wherein the plurality of sub-pixels of the display unit comprise a first sub-pixel and a second sub-pixel; and the detection control sub-circuit comprises a first detection control sub-circuit and a second detection control sub-circuit;
a second terminal of a sensing sub-circuit of the first sub-pixel is electrically connected to the sensing signal line through the first detection control sub-circuit; a second terminal of the sensing sub-circuit of the second sub-pixel is electrically connected to the sensing signal line through the second detection control sub-circuit;
the detection scan signal line comprises a first detection scan signal line and a second detection scan signal line, a control terminal of the first detection control sub-circuit is electrically connected to the first detection scan signal line to receive a first detection scan signal, a first terminal of the first detection control sub-circuit is electrically connected to a second terminal of the sensing sub-circuit of the first sub-pixel, and a second terminal of the first detection control sub-circuit is electrically connected to the sensing signal line;
a control terminal of the second detection control sub-circuit is electrically connected to the second detection scan signal line to receive a second detection scan signal, a first terminal of the second detection control sub-circuit is electrically connected to a second terminal of the sensing sub-circuit of the second sub-pixel, and a second terminal of the second detection control sub-circuit is electrically connected to a same one sensing signal line as the sensing signal line.

5. The display substrate according to claim 4, wherein the first detection control sub-circuit comprises a first detection control transistor, the second detection control sub-circuit comprises a second detection control transistor; a first electrode of the first detection control transistor is electrically connected to a second electrode of the sensing transistor of the first sub-pixel, a first electrode of the second detection control transistor is electrically connected to a second electrode of the sensing transistor of the second sub-pixel, a second electrode of the first detection control transistor and a second electrode of the second detection control transistor are respectively electrically connected to the same one sensing signal line;
a gate electrode of the first detection control transistor is electrically connected to the first detection scan signal line to receive a first detection scan signal, and a gate electrode of the second detection control transistor is electrically connected to the second detection scan signal line to receive a second detection scan signal.

6. The display substrate according to claim 4, wherein the plurality of sub-pixels of the display unit further comprises a third sub-pixel, and a second terminal of the sensing sub-circuit of the third sub-pixel is electrically connected to the first terminal of the first detection control sub-circuit; or,
the plurality of sub-pixels of the display unit further comprises a fourth sub-pixel, and a second terminal of the sensing sub-circuit of the fourth sub-pixel is electrically connected to the first terminal of the second detection control sub-circuit, and the second terminal of the second detection control sub-circuit is electrically connected to the sensing signal line.

7. The display substrate according to claim 4, wherein the plurality of sub-pixels of the display unit further comprises a third sub-pixel, and a pixel circuit of the third sub-pixel further comprises a third detection control sub-circuit;
the detection scan signal line comprises a third detection scan signal line, a control terminal of the third detection control sub-circuit is electrically connected to the third detection scan signal line to receive a third detection scan signal, a first terminal of the third detection control sub-circuit is electrically connected to a second terminal of the sensing sub-circuit of the third sub-pixel, and a second terminal of the third detection control sub-circuit is electrically connected to the sensing signal line.

8. The display substrate according to claim 7, wherein the third detection control sub-circuit comprises a third detection control transistor, a gate electrode of the third detection control transistor is electrically connected to the third detection scan signal line, a first electrode of the third detection control transistor is electrically connected to a second electrode of a sensing transistor of the third sub-pixel, and a second electrode of the third detection control transistor is electrically connected to the sensing signal line.

9. The display substrate according to claim 4, wherein the plurality of sub-pixels of the display unit further comprises a third sub-pixel, and a pixel circuit of the third sub-pixel further comprises a third detection control sub-circuit;
the detection scan signal line comprises a third detection scan signal line, a control terminal of the third detection control sub-circuit is electrically connected to the third detection scan signal line to receive a third detection scan signal, a first terminal of the third detection control sub-circuit is electrically connected to a second terminal of the sensing sub-circuit of the third sub-pixel, and a second terminal of the third detection control sub-circuit is electrically connected to the first terminal of the first detection control sub-circuit.

10. The display substrate according to claim 9, wherein the third detection control sub-circuit comprises a third detection control transistor, a gate electrode of the third detection control transistor is electrically connected to the third detection scan signal line, and is configured to receive the third detection scan signal, a first electrode of the third detection control transistor is electrically connected to a second electrode of the sensing transistor of the third sub-pixel, and a second electrode of the third detection control transistor is electrically connected to a first electrode of the first detection control transistor.

11. (canceled)

12. The display substrate according to claim 4, wherein the plurality of sub-pixels of the display unit further comprises a fourth sub-pixel, and a pixel circuit of the fourth sub-pixel further comprises a fourth detection control sub-circuit;
the detection scan signal line comprises a fourth detection scan signal line, a control terminal of the fourth detection control sub-circuit is electrically connected to the fourth detection scan signal line to receive a fourth detection scan signal, a first terminal of the fourth detection control sub-circuit is electrically connected to a second terminal of the sensing sub-circuit of the fourth sub-pixel, and a second terminal of the fourth detection control sub-circuit is electrically connected to the sensing signal line.

13. The display substrate according to claim 12, wherein the fourth detection control sub-circuit comprises a fourth detection control transistor, a gate electrode of the fourth detection control transistor is electrically connected to the fourth detection scan signal line to receive the fourth detection scan signal, a first electrode of the fourth detection control transistor is electrically connected to a second electrode of the sensing transistor of the fourth sub-pixel, and a second electrode of the fourth detection control transistor is electrically connected to the sensing signal line.

14. The display substrate according to claim 5, wherein the plurality of sub-pixels of the display unit further comprises a fourth sub-pixel, and a pixel circuit of the fourth sub-pixel further comprises a fourth detection control sub-circuit;
the detection scan signal line comprises a fourth detection scan signal line, a control terminal of the fourth detection control sub-circuit is electrically connected to the fourth detection scan signal line to receive the fourth detection scan signal, a first terminal of the fourth detection control sub-circuit is electrically connected to a second terminal of the sensing sub-Preliminary circuit of the fourth sub-pixel, and a second terminal of the fourth detection control sub-circuit is electrically connected to a first terminal of the second detection control sub-circuit.

15. The display substrate according to claim 14, wherein the fourth detection control sub-circuit comprises a fourth detection control transistor, a gate electrode of the fourth detection control transistor is configured to receive the fourth detection scan signal, a first electrode of the fourth detection control transistor is electrically connected to a second electrode of the sensing transistor of the fourth sub-pixel, and a second electrode of the fourth detection control transistor is electrically connected to a first electrode of the second detection control transistor.

16. A detection method of a display substrate, wherein the display substrate comprises a display unit, the display unit is located in a display region and performs a display function, the display unit comprises a plurality of sub-pixels, and each of the plurality of sub-pixels comprises a pixel circuit;
the pixel circuit comprises: a driving sub-circuit, a light-emitting element and a sensing sub-circuit, a first terminal of the sensing sub-circuit is electrically connected to a first terminal of the driving sub-circuit and a first electrode of the light-emitting element;
the display substrate comprises a sensing signal line, a sensing scan signal line and a detection scan signal line, a control terminal of the sensing sub-circuit is electrically connected to the sensing scan signal line, the sensing sub-circuit is configured to detect an electrical characteristic of a sub-pixel to which the sensing sub-circuit belongs through the sensing signal line, in response to a sensing scan signal;
among the plurality of sub-pixels of the display unit, a pixel circuit of at least one sub-pixel includes a detection control sub-circuit, wherein a control terminal of the detection control sub-circuit is electrically connected to the detection scan signal line to receive a detection scan signal. a first terminal of the detection control sub-circuit is electrically connected to a second terminal of the sensing sub-circuit, and a second terminal of the detection control sub-circuit is electrically connected to the sensing signal line;
the detection method comprises: performing at least two times of detections on at least one sub-pixel among the plurality of sub-pixels of the display unit, and performing at least two times of detections on electrical signals on the sensing signal line, which specifically comprises:
in a first detection, turning on detection control transistors of all the sub-pixels included in the display unit, and if an electrical signal on the sensing signal line is abnormal, then performing a next detection;
in a next detection, turning off a detection control transistor of at least one sub-pixel among the plurality of sub-pixel in the display unit to detect other sub-pixels in the display unit again;
determining whether the plurality of sub-pixels are abnormal based on the electrical signals on the sensing signal line obtained by the two times of detections; and
for an abnormal sub-pixel, obtaining a threshold voltage of a driving sub-circuit of a sub-pixel with a same color as the abnormal sub-pixel and without abnormality in another display unit as a threshold voltage of the driving sub-circuit of the abnormal sub-pixel for a compensation on the abnormal sub-pixel.

17. The detection method of a display substrate according to claim 16, wherein the pixel circuit further comprises a data writing sub-circuit, the data writing sub-circuit is configured to write a data signal to a control terminal of the driving sub-circuit in response to a data scan signal;
performing at least two times of detections on at least one sub-pixel among the plurality of sub-pixels of the display unit comprises: using the at least one sub-pixel among the plurality of sub-pixels of the display unit as a test sub-pixel to perform the two times of detections, wherein during a process of performing the two times of detections on the test sub-pixel, the data signal is written to the test sub-pixel and the data signal is not written to other sub-pixels except the test sub-pixel, and the first detection scan signal and the second detection scan signal in the first detection to be not completely same as the first detection scan signal and the second detection scan signal in the second detection in the process of the two times of detections are controlled.

18. The detection method of the display substrate according to claim 17, wherein the detection method comprises:
in the first detection, turning on the detection control transistors of all the sub-pixels included in the display unit, and performing the first detection on an electrical signal on the sensing signal line, if a detected detection signal on the sensing signal line is abnormal, then it indicates that at least one sub-pixel among the plurality of sub-pixels in the display unit has a short circuit problem of a sensing transistor, then randomly turning off the detection control transistor of at least one sub-pixel among the plurality of sub-pixels in the display unit, and performing a second detection using a sub-pixel being not turned off as the test sub-pixel; and
in the second detection, if a detected detection signal on the sensing signal line is abnormal, then it indicates that another sub-pixel except the sub-pixel whose detection control transistor is turned off has a short circuit problem of the sensing transistor, if a detected detection signal on the sensing signal line is normal, it indicates that at least one sub-pixel among the plurality of sub-pixels whose detection control transistor is turned off has a short circuit problem of the sensing transistor.

19. The detection method of the display substrate according to claim 17, wherein, in a case that the plurality of sub-pixels in the display unit comprises a first sub-pixel and a second sub-pixel, the first sub-pixel comprises a first detection control transistor, the second sub-pixel comprises a second detection control transistor, a first electrode of the first detection control transistor is electrically connected to a second electrode of a sensing transistor of the first sub-pixel, a first electrode of the second detection control transistor is electrically connected to a second electrode of a sensing transistor of the second sub-pixel, and a second electrode of the first detection control transistor and a second electrode of the second detection control transistor are respectively electrically connected to a same one sensing signal line as the sensing signal line, a gate electrode of the first detection control transistor is electrically connected to a first detection scan signal line to receive a first detection scan signal, and a gate electrode of the second detection control transistor is electrically connected to a second detection scan signal line to receive a second detection scan signal, the detection method comprises:
in the first detection, turning on both the first detection control transistor and the second detection control transistor, in response to a detected detection signal of the sensing signal line being abnormal, randomly turning off the first detection control transistor or the second detection control transistor, and then using a sub-pixel whose detection control transistor is not turned off as the test sub-pixel to perform the second detection; and
in the second detection, if a detected detection signal of the sensing signal line is abnormal, it indicates that the sensing transistor of the test sub-pixel is abnormal, if a detected detection signal of the sensing signal line is normal, it indicates that the sensing transistor of another sub-pixel except the test sub-pixel is abnormal;
in a case that the plurality of sub-pixels in the display unit further comprises a third sub-pixel, a pixel circuit of the third sub-pixel further comprises a third detection control sub-circuit, the detection scan signal line comprises a third detection scan signal line, a control terminal of the third detection control sub-circuit is electrically connected to the third detection scan signal line to receive a third detection scan signal, a first terminal of the third detection control sub-circuit is electrically connected to a second terminal of the sensing sub-circuit of the third sub-pixel, and a second terminal of the third detection control sub-circuit is electrically connected to the sensing signal line,
the detection method comprises:
using one sub-pixel among the plurality of sub-pixels in the display unit as the test sub-pixel to perform two times of detections on electrical signals on the sensing signal line, which specifically comprises:
in the first detection, turning on detection control transistors of all sub-pixels included in the display unit, and performing the first detection on an electrical signal on the sensing signal line, if a detected detection signal on the sensing signal line is abnormal, then it indicates that at least one sub-pixel among the plurality of sub-pixels in the display unit has a short circuit problem of a sensing transistor, then randomly turning off detection control transistors of two sub-pixels except the test sub-pixel in the display unit, and performing a second detection on an electrical signal on the sensing signal line; and
in the second detection, if a detected detection signal on the sensing signal line is normal, then it indicates that at least one of the two sub-pixels whose detection control transistors are turned off have a short circuit problem of a sensing transistor, if a detected detection signal on the sensing signal line is abnormal, it indicates that the test sub-pixel has a short circuit problem of a sensing transistor.

20. (canceled)

21. (canceled)

22. A display substrate, comprising a display unit, wherein the display unit is located in a display region and performs a display function, the display unit comprises a plurality of sub-pixels, and each of the plurality of sub-pixels comprises a pixel circuit;
the pixel circuit comprises: a driving sub-circuit, a light-emitting element and a sensing sub-circuit, the driving sub-circuit is configured to control a magnitude of a driving current flowing through the light-emitting element;
a control terminal of the sensing sub-circuit is configured to receive a sensing scan signal, a first terminal of the sensing sub-circuit is electrically connected to a first terminal of the driving sub-circuit and a first electrode of the light-emitting element; the display substrate comprises a plurality of sensing signal lines, a second terminal of the sensing sub-circuit is electrically connected to a corresponding one sensing signal line among the plurality of sensing signal lines, and the sensing sub-circuit is configured to detect an electrical characteristic of the sub-pixel to which the sensing sub-circuit belongs through the sensing signal line electrically connected thereto in respond to the received sensing scan signal;
the plurality of sub-pixels in the display unit comprises a first sub-pixel, a second sub-pixel and a third sub-pixel;
a second terminal of a sensing sub-circuit of the first sub-pixel and a second terminal of the sensing sub-circuit of the second sub-pixel are electrically connected to a same one sensing signal line among the plurality of sensing signal lines, a second terminal of the sensing sub-circuit of the third sub-pixel and a second terminal of the sensing sub-circuit of the first sub-pixel are respectively electrically connected to different sensing signal lines, and,
a control terminal of the sensing sub-circuit of the first sub-pixel and a control terminal of the sensing sub-circuit of the second sub-pixel are respectively electrically connected to different sensing scan signal terminals to receive different sensing scan signals.

23-26. (canceled)

27. A display device, comprising the display substrate according to claim 1.
